(19) United States
(12) Patent Application Publication
(10) Pub. No.: US 2025/0386686 A1
(43) Pub. Date: Dec. 18, 2025

(54) DISPLAY DEVICE

(71) Applicant: Samsung Display Co., LTD., Yongin-si (KR)

(72) Inventors: Sun Kwang KIM, Yongin-si (KR); Guang Hai JIN, Yongin-si (KR); Ki Nyeng KANG, Yongin-si (KR)

(21) Appl. No.: 18/970,657

(22) Filed: Dec. 5, 2024

(30) Foreign Application Priority Data
Jun. 14, 2024 (KR) 10-2024-0077855

(51) Int. Cl. H10K 59/131; H10K 59/122

(52) U.S. Cl. CPC H10K 59/131; H10K 59/122

(57) ABSTRACT

A display device includes a substrate; a common voltage line above the substrate; a first insulating layer above the common voltage line; a connection electrode above the first insulating layer and electrically connected to the common voltage line through a first contact hole of the first insulating layer; a discharge electrode above the first insulating layer and electrically connected to the connection electrode; a pixel electrode above the first insulating layer; a light-emitting portion above the pixel electrode; and a common electrode above the light-emitting portion, the light-emitting portion comprises a light-emitting opening above the connection electrode, the common electrode is electrically connected to the connection electrode through the light-emitting opening, the discharge electrode extends along a space between two adjacent or more pixel electrodes comprising the pixel electrode on a plane, and the discharge electrode overlaps the light-emitting portion and the common electrode to form a discharge diode.

### CROSS-REFERENCE TO RELATED APPLICATION

The present application claims priority to, and the benefit of, Korean Patent Application No. 10-2024-0077855, filed on Jun. 14, 2024, in the Korean Intellectual Property Office, the entire disclosure of which is incorporated herein by reference.

### BACKGROUND

### 1. Field

The present disclosure relates to a light-emitting diode display device including light-emitting diodes.

### 2. Description of the Related Art

A light-emitting diode display device displaying an image by adjusting luminance of light-emitting elements, and a liquid crystal display device displaying an image by adjusting transmittance of a liquid crystal layer, are widely used as display devices. Unlike the liquid crystal display device, the light-emitting diode display device may not require a separate light source, such as a backlight, so thickness and weight of the display device are reduced. In addition, the light-emitting diode display device exhibits a high-quality characteristic, such as low power consumption, high luminance, a high response speed, or the like.

The display device may include a display area corresponding to a screen that displays an image, and pixels may be located at the display area. The pixels may be implemented by light-emitting diodes. The light-emitting diode may include two electrodes and a light-emitting layer located between them. One of the two electrodes may be a pixel electrode individually provided for each pixel, and the other of the two electrodes may be a common electrode provided in common to a plurality of pixels.

The light-emitting diode included in each pixel may include the light-emitting layer and a light-emitting auxiliary layer for assisting light emission. The light-emitting auxiliary layer may include a charge generation layer for helping a current flow between light-emitting portions.

### SUMMARY

Embodiments are intended to reduce or prevent the likelihood of an adjacent pixel unintentionally emitting light due to a leakage current flowing to the adjacent pixel through a charge generation layer when a light-emitting diode of a display device is driven.

A display device according to one or more embodiments includes a substrate, a common voltage line above the substrate, a first insulating layer above the common voltage line, a connection electrode above the first insulating layer, and electrically connected to the common voltage line through a first contact hole of the first insulating layer, a pixel electrode above the first insulating layer, a light-emitting portion above the pixel electrode, and defining a light-emitting opening above the connection electrode, a common electrode above the light-emitting portion, and electrically connected to the connection electrode through the light-emitting opening, and a discharge electrode above the first insulating layer, electrically connected to the connection electrode, extending along a space between two or more adjacent pixel electrodes including the pixel electrode in plan view, and overlapping the light-emitting portion and the common electrode to form a discharge diode.

The display device may further include a second insulating layer above the pixel electrode, and defining a first opening overlapping the pixel electrode, a second opening overlapping the light-emitting opening, and a third opening overlapping the discharge diode.

The discharge electrode may be at a same conductive layer as the connection electrode, and may be integrally formed with the connection electrode.

The display device may include unit pixel groups repeatedly arranged, and including adjacent pixels, wherein the discharge electrode includes a first horizontal portion extending in a first direction, and a first vertical portion extending in a second direction crossing the first direction, the first horizontal portion and the first vertical portion surrounding one of the unit pixel groups with the connection electrode in plan view.

The discharge electrode may include a second horizontal portion extending in the first direction, and a second vertical portion extending in the second direction, wherein the second horizontal portion is between two adjacent first horizontal portions including the first horizontal portion, and has a shorter length than that of the first horizontal portion, and wherein the second vertical portion is between two adjacent first vertical portions including the first vertical portion, and has a shorter length than that of the first vertical portion.

The second horizontal portion and the second vertical portion may extend along a space between the adjacent pixels of one of the unit pixel groups.

The second horizontal portion may be at a center between the two adjacent first horizontal portions in plan view.

The discharge electrode may be at a conductive layer that is different from the connection electrode, and may include a portion overlapping the connection electrode in plan view.

The display device may include unit pixel groups repeatedly arranged and including adjacent pixels, wherein the discharge electrode includes a portion extending along a space between the adjacent pixels of one of the unit pixel groups.

A portion of the discharge electrode overlapping the connection electrode may cross the common voltage line.

The display device may further include a second insulating layer above the pixel electrode, and defining a first opening overlapping the pixel electrode and a second opening overlapping the light-emitting opening, wherein the discharge electrode is above an upper surface of the second insulating layer.

The discharge electrode may be at a conductive layer that is different from the connection electrode, and may include a portion overlapping the connection electrode in plan view.

The display device may include unit pixel groups repeatedly arranged and including adjacent pixels, wherein the discharge electrode includes a portion extending along a space between the adjacent pixels of the unit pixel group.

A display device according to one or more other embodiments includes a substrate, a first transistor and a second transistor above the substrate, a first light-emitting diode and a second light-emitting diode respectively connected to the first transistor and the second transistor, and including a pixel electrode, a common electrode, and a light-emitting portion between the pixel electrode and the common electrode and including stacked unit light-emitting portions and a light-emitting auxiliary layer between adjacent ones of the unit light-emitting portions, the unit light-emitting portions including a light-emitting layer including a light-emitting material, and a discharge diode connected between the first light-emitting diode and the second light-emitting diode, and including the light-emitting auxiliary layer and an anode and a cathode connected to a cathode of the first light-emitting diode.

The light-emitting auxiliary layer in the first light-emitting diode and in the discharge diode may include a charge generation layer.

The display device may further include a common voltage line above the substrate, and a connection electrode connected to the common voltage line, wherein the light-emitting portion defines a light-emitting opening above the connection electrode, and wherein the cathode of the first light-emitting diode is connected to the connection electrode through the light-emitting opening.

The anode of the discharge diode may be at a same conductive layer as the connection electrode, and may be integrally formed with the connection electrode.

The display device may further include an insulating layer between an anode and the cathode of the first light-emitting diode, and defining a first opening overlapping the anode of the first light-emitting diode, a second opening overlapping the light-emitting opening, and a third opening overlapping the anode of the discharge diode.

The anode of the discharge diode may be at a conductive layer that is different from the connection electrode, and may include a portion overlapping the connection electrode in plan view.

The display device may further include an insulating layer between an anode and the cathode of the first light-emitting diode, and defining a first opening overlapping the anode of the first light-emitting diode and a second opening overlapping the light-emitting opening, wherein the anode of the discharge diode is above an upper surface of the insulating layer.

An electronic device according to one or more embodiments may include a display device including a display device including a substrate, a common voltage line above the substrate, a first insulating layer above the common voltage line, a connection electrode above the first insulating layer, and electrically connected to the common voltage line through a first contact hole of the first insulating layer, a pixel electrode above the first insulating layer, a light-emitting portion above the pixel electrode, and defining a light-emitting opening above the connection electrode, a common electrode above the light-emitting portion, and electrically connected to the connection electrode through the light-emitting opening, and a discharge electrode above the first insulating layer, electrically connected to the connection electrode, extending along a space between two or more adjacent pixel electrodes including the pixel electrode in plan view, and overlapping the light-emitting portion and the common electrode to form a discharge diode.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

According to the embodiments, the likelihood of an adjacent pixel unintentionally emitting light due to a leakage current flowing to the adjacent pixel through a charge generation layer when a light-emitting diode of a display device is driven may be reduced or prevented, and a display defect caused by crosstalk between pixels may be reduced or prevented.

### BRIEF DESCRIPTION OF THE DRAWINGS

FIG. 1 is a schematic plan view of a display device according to one or more embodiments.

FIG. 2 is a circuit diagram of one pixel of a display device according to one or more embodiments.

FIG. 3 is a plan view of a display portion of a display device according to one or more embodiments.

FIG. 4 is a cross-sectional view of the display device shown in FIG. 3 that is cut along the line A-A′.

FIG. 5 is a cross-sectional view of the display device shown in FIG. 3 that is cut along the line B-B′.

FIG. 6 is a cross-sectional view of the display device shown in FIG. 3 that is cut along the line C-C′.

FIG. 7, FIG. 8, FIG. 9, FIG. 10, FIG. 11, and FIG. 12 are plan views showing the display device illustrated in FIG. 3 according to a stacking order on a substrate.

FIG. 13 is a circuit diagram for two pixels of a display device according to one or more embodiments.

FIG. 14 is a cross-sectional view of a light-emitting diode included in one pixel of a display device according to one or more embodiments.

FIG. 15 is a plan view of a display portion of a display device according to one or more embodiments.

FIG. 16 is a cross-sectional view of the display device shown in FIG. 15 that is cut along the line D-D′.

FIG. 17 is a cross-sectional view of the display device shown in FIG. 15 that is cut along the line D-D′.

FIG. 18 is a cross-sectional view of the display device shown in FIG. 15 that is cut along the line E-E′.

FIG. 19 is a cross-sectional view of a display panel of a display device according to one or more embodiments.

FIG. 20 is a block diagram of an electronic device according to an embodiment.

FIG. 21 to FIG. 23 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

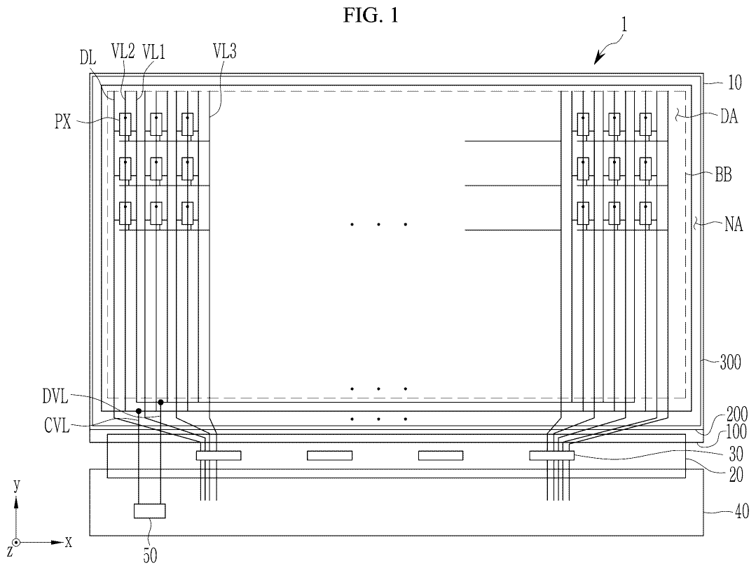

FIG. 1 is a schematic plan view of a display device according to one or more embodiments.

Referring to FIG. 1, a light-emitting diode display device 1 (hereinafter, referred to as the display device) may include a display panel 10, a flexible printed circuit film 20, a driving integrated circuit chip 30, a printed circuit board 40, a power module 50, and the like.

The display panel 10 may include a display area DA corresponding to a screen for displaying an image, and a non-display area NA in which circuits and/or wires for generating and/or transferring various signals applied to the display area DA are located. The non-display area NA may be adjacent to the display area DA, and may surround the display area DA (e.g., in plan view). In FIG. 1, an inner area and an outer area of a boundary line BB may be the display area DA and the non-display area NA, respectively.

The display panel 10 may include a display portion 100 and a color conversion portion 200. The display portion 100 and the color conversion portion 200 may be bonded by a sealant 300 located around an edge of the display panel 10 between the display portion 100 and the color conversion portion 200. The color conversion portion 200 may entirely overlap the display portion 100, but the display portion 100 may include an area not covered by the color conversion portion 200 for connecting or bonding the flexible printed circuit film 20. In one or more embodiments, the display portion 100 may include a pad portion for connecting or bonding the flexible printed circuit film 20, and the color conversion portion 200 may be shorter than the display portion 100 in an area in which the pad portion is located so that the pad portion is exposed to the outside (for example, at a lower end portion of the display panel 10). Each of the display portion 100 and the color conversion portion 200 may include areas corresponding to the display area DA and the non-display area NA of the display panel 10.

The display area DA of the display panel 10 may include a plurality of pixels PX that are units capable of displaying an image. The plurality of pixels PX may be located on a regular manner (for example, in a matrix form). A data line DL that transfers a data voltage Data, a driving voltage line VL1 that transfers a driving voltage ELVDD, a common voltage line VL2 that transfers a common voltage ELVSS, and an initialization voltage line VL3 that transfers an initialization voltage INIT may be located on the display area DA. The driving voltage line VL1, the common voltage line VL2, and the initialization voltage line VL3 may extend in the second direction (y). The driving voltage line VL1, the common voltage line VL2, and/or the initialization voltage line VL3 may be connected to an auxiliary voltage line extending in the first direction (x). Each pixel PX may receive the data voltage Data, the driving voltage ELVDD, the common voltage ELVSS, and the initialization voltage INIT from the voltage lines DL, VL1, VL2, and VL3. The driving voltage ELVDD and the common voltage ELVSS may be power supply voltages applied to each pixel PX, and the driving voltage line VL1 and the common voltage line VL2 transferring the power supply voltages may be referred to as power supply voltage lines. The driving voltage ELVDD may be a higher voltage than the common voltage ELVSS. The driving voltage ELVDD may be referred to as a first power supply voltage or a high-potential power supply voltage. The common voltage ELVSS may be referred to as a second power supply voltage or a low-potential power supply voltage.

In one or more embodiments, gate-driving portions may be located on both sides of the display area DA in the non-display area NA of the display panel 10. The gate-driving portion may be integrated into the non-display area NA. The pixels PX may receive a gate signal (also referred to as a scan signal) generated from the gate-driving portion to receive the data voltage Data at a given timing (e.g., a predetermined timing).

A driving voltage transfer line DVL connected to driving voltage lines VL1, a common voltage transfer line CVL connected to common voltage lines VL2, and the like may be located on the non-display area NA of the display panel 10. Each of the driving voltage transfer line DVL and the common voltage transfer line CVL may include portions extending approximately in the second direction (y) and portions extending approximately in the first direction (x). The common voltage transfer line CVL may surround the display area DA. The common voltage lines VL2 may be connected to the common voltage transfer line CVL at lower and upper sides of the display area DA, so that they substantially uniformly supply the common voltage ELVSS throughout the display area DA.

The flexible printed circuit film 20 may have one end connected or bonded to the display portion 100 of the display panel 10 and the other end connected or bonded to the printed circuit board 40. The driving integrated circuit chip 30 including a data driving portion applying the data voltage Data to the data line DL may be located on the flexible printed circuit film 20.

The power module 50 generating the power supply voltage, such as the driving voltage ELVDD or the common voltage ELVSS, may be located on the printed circuit board 40. The power module 50 may be provided in a form of an integrated circuit chip. In one or more embodiments, a signal control portion that controls the data driving portion and the gate-driving portion may be located on the printed circuit board 40.

The display device 1 according to one or more embodiments is a device that displays a moving image and/or a still image. The display device 1 may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the display device 1 may be applied to a display unit of a television, a laptop computer, a monitor, a billboard, or the Internet of Things (IoT). Alternatively, in one or more embodiments, the display device 1 may be applied to a smartwatch, a watch phone, and/or a head-mounted display device (HMD) for implementing virtual reality and/or augmented reality.

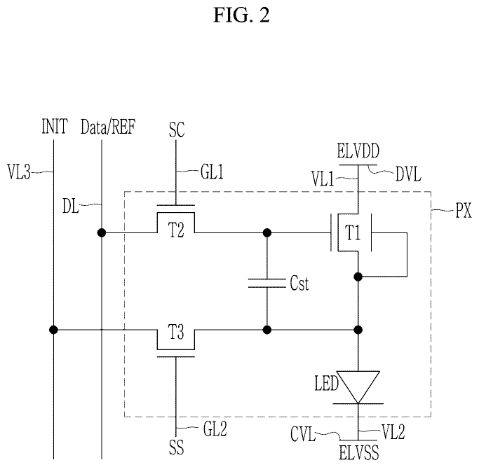

FIG. 2 is a circuit diagram of one pixel of the display device according to one or more embodiments.

Referring to FIG. 2, the pixel PX may include first to third transistors T1-T3, a storage capacitor Cst, and a light-emitting diode LED. The light-emitting diode LED may be an organic or inorganic light-emitting diode. The first to third transistors T1-T3 may be n-type transistors, and at least some thereof may be p-type transistors.

A gate electrode of the first transistor T1 may be connected to a first electrode of the storage capacitor Cst. A first electrode of the first transistor T1 may be connected to the driving voltage line VL1 that transfers the driving voltage ELVDD, and a second electrode of the first transistor T1 may be connected to an anode of the light-emitting diode LED and to a second electrode of the storage capacitor Cst. The first transistor T1 may receive the data voltage Data according to a switching operation of the second transistor T2 to supply a driving current to the light-emitting diode LED according to a voltage stored in the storage capacitor Cst.

A gate electrode of the second transistor T2 may be connected to a first gate line GL1 that transfers a first scan signal SC. A first electrode of the second transistor T2 may be connected to the data line DL that may transfer the data voltage Data or a reference voltage REF. A second electrode of the second transistor T2 may be connected to the first electrode of the storage capacitor Cst and the gate electrode of the first transistor T1. The second transistor T2 may be turned on according to the first scan signal SC to transfer the reference voltage REF or the data voltage Data to the gate electrode of the first transistor T1.

A gate electrode of the third transistor T3 may be connected to a second gate line GL2 that transfers a second scan signal SS. A first electrode of the third transistor T3 may be connected to the initialization voltage line VL3 that transfers the initialization voltage INIT. A second electrode of the third transistor T3 may be connected to the second electrode of the storage capacitor Cst, to the second electrode of the first transistor T1, and to the anode. The third transistor T3 may be turned on according to the second scan signal SS to transfer the initialization voltage INIT to the anode, allowing the third transistor T3 to initialize a voltage of the anode.

The first electrode of the storage capacitor Cst may be connected to the gate electrode of the first transistor T1, and the second electrode of the storage capacitor Cst may be connected to the second electrode of the third transistor T3 and to the anode. A cathode of the light-emitting diode LED may be connected to the common voltage line VL2 that transfers the common voltage ELVSS. Each pixel PX may include at least one light-emitting diode LED, and the anode and the cathode of the light-emitting diode LED may be referred to as a pixel electrode and a common electrode, respectively

The light-emitting diode LED may emit light having luminance (e.g., gray scale) according to the driving current generated by the first transistor T1.

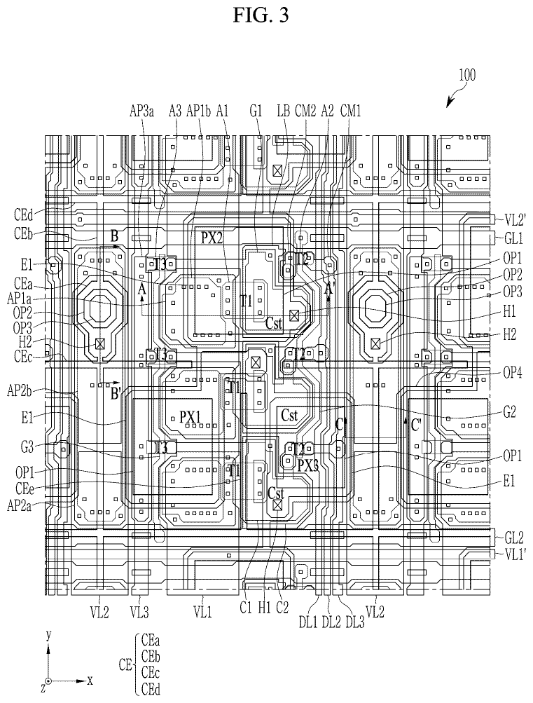

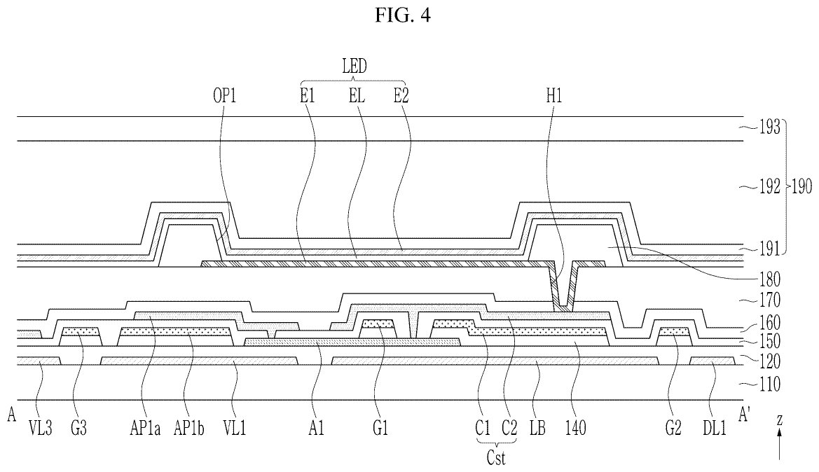

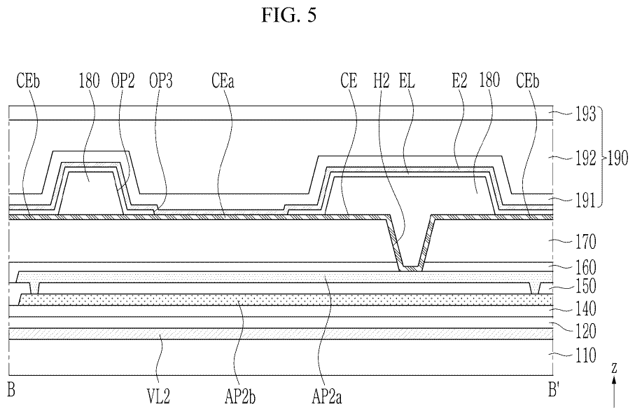

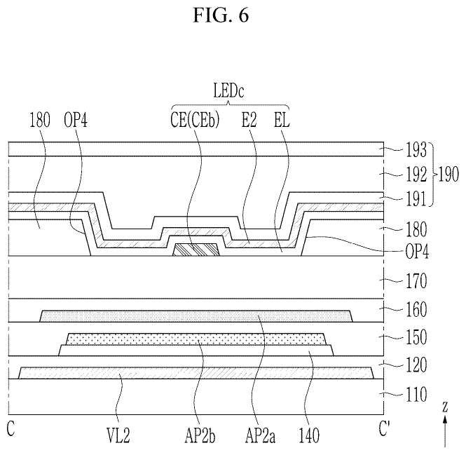

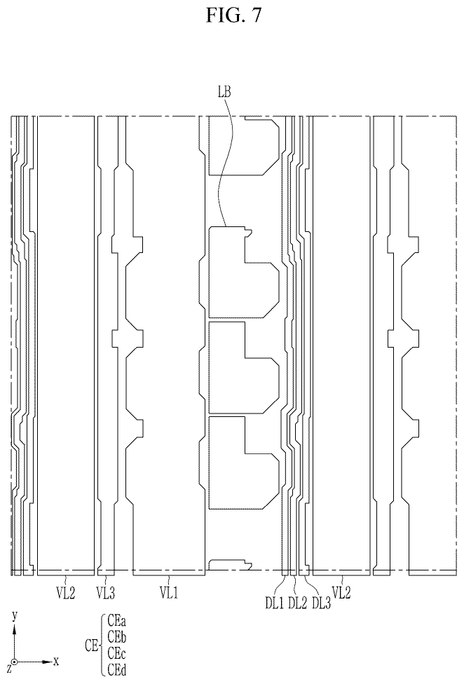

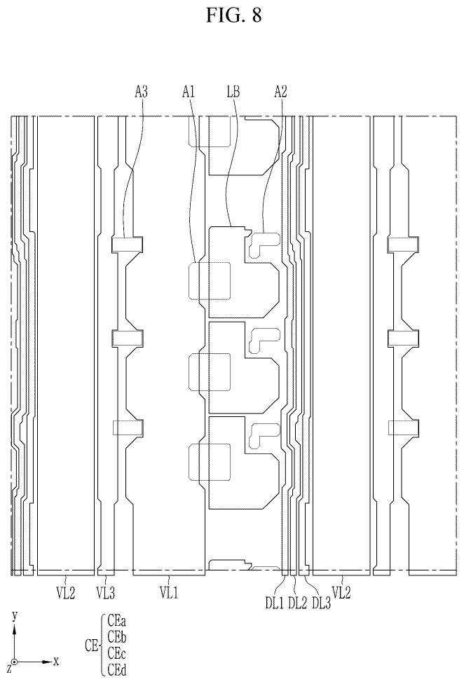

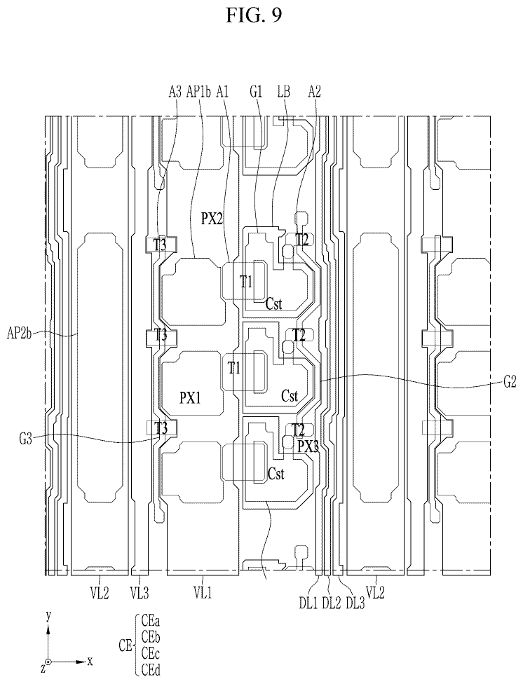

FIG. 3 is a plan view of a display portion of the display device of one or more embodiments, FIG. 4 is a cross-sectional view of the display device shown in FIG. 3 that is cut along the line A-A′, FIG. 5 is a cross-sectional view of the display device shown in FIG. 3 that is cut along the line B-B′, FIG. 6 is a cross-sectional view of the display device shown in FIG. 3 that is cut along the line C-C′, and FIG. 7, FIG. 8, FIG. 9, FIG. 10, FIG. 11, and FIG. 12 are plan views showing the display device illustrated in FIG. 3 according to a stacking order on a substrate.

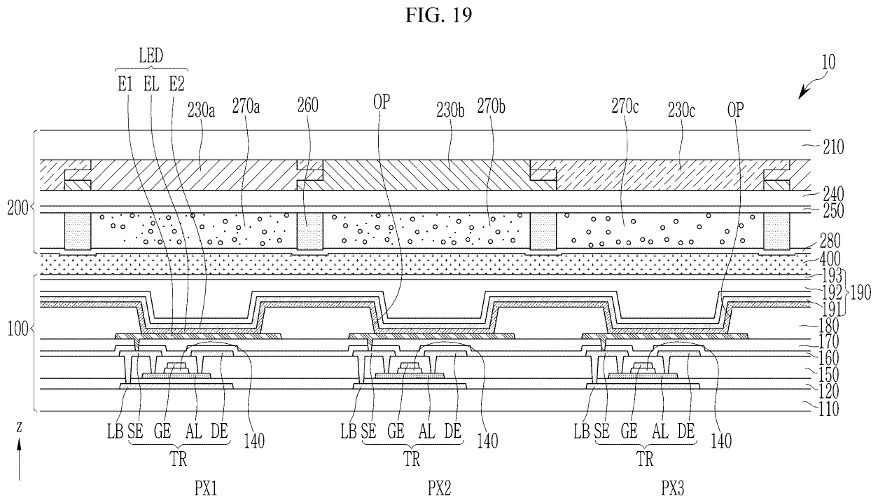

FIG. 3 shows three adjacent pixels PX1, PX2, and PX3, and wires connected thereto, in the display panel 10 included in the display device according to one or more embodiments. The pixels PX1, PX2, and PX3 may be repeatedly located on a matrix form in the display area. Here, the display portion 100 of the display panel 10 will be mainly described, and the color conversion portion 200 of the display panel 10 will be described later with reference to FIG. 19.

Referring to FIGS. 3 to 6, the display portion 100 may include the light-emitting diode LED corresponding to each of the pixels PX1, PX2, and PX3. The pixels PX1, PX2, and PX3 may include the first pixel PX1, the second pixel PX2, and the third pixel PX3 that emit different colors. For example, one of the first pixel PX1, the second pixel PX2 and the third pixel PX3 may display red, another thereof may display green, and the other thereof may display blue.

The display portion 100 may include the substrate 110, the first to third transistors T1, T2, and T3 and the storage capacitor Cst formed above the substrate 110, and the light-emitting diode LED connected to the first transistor T1.

The substrate 110 may include a material having a rigid characteristic, such as glass, or a material having a flexible characteristic, such as plastic.

A first conductive layer including the data lines DL1, DL2, and DL3, the driving voltage line VL1, the common voltage line VL2, the initialization voltage line VL3, a light-blocking pattern LB, and the like may be located on the substrate 110 (as used herein, “located on” may mean “above”). Components included in the first conductive layer may be formed of the same material in the same process. For example, a conductive layer may be deposited and patterned on the substrate 110 to form the data lines DL1, DL2, and DL3, the driving voltage line VL1, the common voltage line VL2, the initialization voltage line VL3, the light-blocking pattern LB, and the like. FIG. 7 shows the first conductive layer.

The data lines DL1, DL2, and DL3 may include the first data line DL1 that transfers the data voltage Data to the first pixel PX1, the second data line DL2 that transfers the data voltage Data to the second pixel PX2, and the third data line DL3 that transfers the data voltage Data to the third pixel PX3. The first data line DL1, the second data line DL2, and the third data line DL3 may be arranged adjacent to each other in the first direction (x), and may extend in the second direction (y).

The driving voltage line VL1 may transfer the driving voltage ELVDD, the common voltage line VL2 may transfer the common voltage ELVSS, and the initialization voltage line VL3 may transfer the initialization voltage INIT. Each of the driving voltage line VL1, the common voltage line VL2, and the initialization voltage line VL3 may extend in the second direction (y).

The common voltage line VL2, the initialization voltage line VL3, the driving voltage line VL1, and the data lines DL1, DL2, and DL3 may be repeatedly located along the first direction (x). The driving voltage line VL1 may be located between the initialization voltage line VL3 and the data lines DL1, DL2, and DL3 in the first direction (x). The common voltage line VL2 may be located between the initialization voltage line VL3 and the data lines DL1, DL2, and DL3 in the first direction (x). The initialization voltage line VL3 may be located between the common voltage line VL2 and the driving voltage line VL1 in the first direction (x). A relative disposition between the voltage lines VL1, VL2, and VL3 and the data lines DL1, DL2, and DL3 may be variously changed.

The light-blocking pattern LB may be located between the driving voltage line VL1 and the data lines DL1, DL2, and DL3. The light-blocking pattern LB may reduce or prevent external light reaching a semiconductor layer A1 of the first transistor T1 to reduce or prevent characteristic deterioration of the semiconductor layer A1. A leakage current of the first transistor T1 (for example, a driving transistor in which a current characteristic is a consideration in the display device) may be controlled by the light-blocking pattern LB. The light-blocking pattern LB may function as an electrode to which a specific voltage is applied. In this case, a current change rate in a saturation region of a voltage-current characteristic graph of the first transistor T1 may be reduced, so that a characteristic of the driving transistor is improved.

The first conductive layer may include a metal, such as copper (Cu), aluminum (Al), titanium (Ti), molybdenum (Mo), tungsten (W), or the like, and may be a single layer or multiple layers. For example, the first conductive layer may have a double-layer structure, such as titanium (Ti)/copper (Cu).

A buffer layer 120 may be located on the first conductive layer. The buffer layer 120 may block an impurity from the substrate 110 when semiconductor layers A1, A2, and A3 are formed to reduce or prevent characteristic deterioration of the semiconductor layers A1, A2, and A3, and may planarize a surface of the substrate 110 to relieve stress on the semiconductor layers A1, A2, and A3. The buffer layer 120 may include an inorganic insulating material, such as silicon nitride (SiNₓ), silicon oxide (SiOₓ), silicon oxynitride (SiOₓN_{y}), or the like. The buffer layer 120 may include amorphous silicon.

The semiconductor layers A1, A2, and A3 may be located on the buffer layer 120. FIG. 8 shows the first conductive layer and the semiconductor layers A1, A2, and A3.

The semiconductor layers A1, A2, and A3 may include the semiconductor layer A1 of the first transistor T1, the semiconductor layer A2 of the second transistor T2, and the semiconductor layer A3 of the third transistor T3. The semiconductor layers A1, A2, and A3 may include a first area and a second area that are conductive areas, and a channel area between the first area and the second area. The semiconductor layers A1, A2, and A3 may have a planar shape that is longer in the first direction (x) than in the second direction (y). The first area of the semiconductor layer A1 may overlap the driving voltage line VL1, and may be connected to the driving voltage line VL1. The second area and the channel area of the semiconductor layer A1 may overlap the light-blocking pattern LB. The first area of the semiconductor layer A2 may be connected to the data line corresponding to one among the data lines DL1, DL2, and DL3. For example, the first area of the semiconductor layer A1 of the first pixel PX1 may be connected to the first data line DL1, the first area of the semiconductor layer A2 of the second pixel PX2 may be connected to the second data line DL2, and the first area of the semiconductor layer A3 of the third pixel PX3 may be connected to the third data line DL3. The second area of the semiconductor layer A2 may be connected to a first electrode C1 of the storage capacitor Cst. The first area of the semiconductor layer A3 may be connected to the initialization voltage line VL3. The second area of the semiconductor layer A3 may be connected to a second electrode C2 of the storage capacitor Cst.

The semiconductor layers A1, A2, and A3 may include oxide semiconductors. For example, the semiconductor layers A1, A2, and A3 may include an oxide semiconductor, such as indium-gallium-zinc oxide (IGZO) that includes at least one of zinc (Zn), indium (In), gallium (Ga), tin (Sn), and a mixture thereof. The semiconductor layers A1, A2, and A3 may include polycrystalline silicon or amorphous silicon. For example, the semiconductor layers may include low-temperature polysilicon (LTPS).

A first insulating layer 140 may be located on the semiconductor layers A1, A2, and A3. The first insulating layer 140 may be referred to as a gate-insulating layer. The first insulating layer 140 may be formed in an area overlapping gate electrodes G1, G2, and G3, the first electrode C1, and auxiliary patterns AP1b and AP2b. The structure may be formed by etching the first insulating layer 140 during a photolithography process for forming the gate electrodes G1, G2, and G3, the first electrode C1, and the auxiliary patterns AP1b and AP2b. According to one or more other embodiments, the first insulating layer 140 may be formed to substantially cover an entire substrate 110. The first insulating layer 140 may be an inorganic insulating layer including an inorganic insulating material, such as silicon oxide, silicon nitride, silicon oxynitride, or the like, and may be a single layer or multiple layers.

A second conductive layer, which may include the gate electrode G1 of the first transistor T1, the gate electrode G2 of the second transistor T2, the gate electrode G3 of the third transistor T3, the first electrode C1 of the storage capacitor Cst, the auxiliary pattern AP1b of the driving voltage line VL1, the auxiliary pattern AP2b of the common voltage line VL2, and the like, may be located on the first insulating layer 140. Components included in the second conductive layer may be formed of the same material in the same process. FIG. 9 shows the first conductive layer, the semiconductor layers A1, A2, and A3, and the second conductive layer.

The gate electrodes G1, G2, and G3 may respectively overlap the channel areas of the semiconductor layers A1, A2, and A3 corresponding to the gate electrodes G1, G2, and G3. The gate electrode G1 may be connected to the first electrode C1. The gate electrode G1 and the first electrode C1 may be integrally formed. The gate electrode G1 and the first electrode C1 may overlap the light-blocking pattern LB. The first electrode C1 may be connected to the second area of the semiconductor layer A2. Gate electrodes G2 of second transistors T2 of the first pixel PX1, the second pixel PX2, and the third pixel PX3 may be connected to each other, and may be integrally formed. The gate electrodes G2 of the second transistors T2 of the first pixel PX1, the second pixel PX2, and the third pixel PX3 may extend approximately or generally in the second direction (y). The second transistors T2 of the first pixel PX1, the second pixel PX2, and the third pixel PX3 may receive the same first scan signal SC.

Gate electrodes G3 of third transistors T3 of the first pixel PX1, the second pixel PX2, and the third pixel PX3 may be connected to each other, and may be integrally formed. The gate electrodes G3 of the third transistors T3 of the first pixel PX1, the second pixel PX2, and the third pixel PX3 may extend approximately in the second direction (y). The third transistors T3 of the first pixel PX1, the second pixel PX2, and the third pixel PX3 may receive the same second scan signal SS.

The auxiliary pattern AP1b of the driving voltage line VL1 may overlap the driving voltage line VL1. The auxiliary pattern AP1b may be located between the gate electrode G3 and the semiconductor layer A1 in the first direction (x). A plurality of auxiliary patterns AP1b may be spaced apart from each other in the second direction (y). The auxiliary pattern AP1b may be connected to the driving voltage line VL1 to reduce a resistance of the driving voltage line VL1, and to reduce an RC delay of the driving voltage ELVDD.

The auxiliary pattern AP2b of the common voltage line VL2 may overlap the common voltage line VL2. On a plane, each auxiliary pattern AP2b may overlap the common voltage line VL2 so that an entire auxiliary pattern is located within the common voltage line VL2 (e.g., in plan view). The auxiliary pattern AP2b may be elongated in the second direction (y), and may be located between the first gate line GL1 and the second gate line GL2. The auxiliary pattern AP2b may be repeatedly located in the second direction (y). The auxiliary pattern AP2b may be connected to the common voltage line VL2 to reduce a resistance of the common voltage line VL2, and to reduce the RC delay of the common voltage ELVSS.

The second conductive layer may include a metal, such as copper (Cu), aluminum (Al), titanium (Ti), molybdenum (Mo), tungsten (W), or the like, and may be a single layer or multiple layers. For example, the second conductive layer may have a double-layer structure, such as titanium (Ti)/copper (Cu).

A second insulating layer 150 may be located on the second conductive layer. The second insulating layer 150 may be referred to as an interlayer insulating layer. The second insulating layer 150 may be an inorganic insulating layer including an inorganic insulating material, such as silicon oxide, silicon nitride, silicon oxynitride, or the like, and may be a single layer or multiple layers.

FIG. 10 shows the first conductive layer, the semiconductor layers A1, A2, and A3, the second conductive layer, and the third conductive layer. A third conductive layer that may include the first gate line GL1, the second gate line GL2, the second electrode C2 of the storage capacitor Cst, an auxiliary driving voltage line VL1′, an auxiliary common voltage line VL2′, an auxiliary pattern AP1a of the driving voltage line VL1, an auxiliary pattern AP2a of the common voltage line VL2, an auxiliary pattern AP3a of the initialization voltage line VL3, and the like, may be located on the second insulating layer 150. Components included in the third conductive layer may be formed of the same material in the same process.

The first gate line GL1 and the second gate line GL2 may extend in the first direction (x). The first gate line GL1 may be connected to the gate electrode G2 through a contact hole formed in the second insulating layer 150, and may transfer the first scan signal SC. The second gate line GL2 may be connected to the gate electrode G3 through a contact hole formed in the second insulating layer 150, and may transfer the second scan signal SS.

The second electrode C2 of the storage capacitor Cst may overlap the first electrode C1, and may form the storage capacitor Cst together with the first electrode C1. The second electrode C2 may overlap the second area of the semiconductor layer A1, and the first electrode C1 may include an opening that overlaps the second area of the semiconductor layer A1. The second electrode C2 may be connected to the second area of the semiconductor layer A1 through the contact hole of the second insulating layer 150 and the opening of the first electrode C1. The second electrode C2 may be connected to the light-blocking pattern LB through contact holes formed in the second insulating layer 150 and the buffer layer 120. Accordingly, the light-blocking pattern LB, the first electrode C1, and the second electrode C2 may form a dual storage capacitor Cst. The second electrode C2 may include an extension portion extending across the driving voltage line VL1 in the first direction (x) to overlap the second area of the semiconductor layer A3, and the extension portion may be connected to the second area of the semiconductor layer A3 through a contact hole formed in the second insulating layer 150.

The auxiliary driving voltage line VL1′ and the auxiliary common voltage line VL2′ may extend in the first direction (x). The auxiliary driving voltage line VL1′ may be connected to the driving voltage line VL1 through contact holes formed in the second insulating layer 150 and the buffer layer 120. The auxiliary common voltage line VL2′ may be connected to the common voltage line VL2 through contact holes formed in the second insulating layer 150 and the buffer layer 120. Accordingly, wires transferring the driving voltage ELVDD may be connected to each other in a mesh form in the display area DA, and a substantially uniform driving voltage ELVDD may be provided throughout an entire display area DA. Wires transferring the common voltage ELVSS may be connected to each other in a mesh form in the display area DA, and a substantially uniform common voltage ELVSS may be provided throughout the display area DA.

The auxiliary pattern AP1a of the driving voltage line VL1 may overlap the driving voltage line VL1 and the auxiliary pattern AP1b. The auxiliary pattern AP1a may be located between the gate electrode G3 and the semiconductor layer A1 in the first direction (x). A plurality of auxiliary patterns AP1a may be spaced apart from each other in the second direction (y). The auxiliary pattern AP1a may be connected to the driving voltage line VL1 to reduce a resistance of the driving voltage line VL1, and to reduce an RC delay of the driving voltage ELVDD. The auxiliary pattern AP1a may be connected to the auxiliary pattern AP1b through a contact hole formed in the second insulating layer 150, may be connected to the driving voltage line VL1 through contact holes formed in the second insulating layer 150 and the buffer layer 120, and may be connected to the first area of the semiconductor layer A1 through a contact hole formed in the second insulating layer 150. Accordingly, each of the auxiliary pattern AP1b and the first transistor T1 may be connected to the driving voltage line VL1 through the auxiliary pattern AP1a.

The auxiliary pattern AP2a of the common voltage line VL2 may overlap the common voltage line VL2 and the auxiliary pattern AP2b. On a plane, each auxiliary pattern AP2a may overlap the common voltage line VL2 so that an entire auxiliary pattern is located within the common voltage line VL2. The auxiliary pattern AP2a may overlap the auxiliary pattern AP2b to cover an entire auxiliary pattern AP2b corresponding to the auxiliary pattern. The auxiliary pattern AP2a may be elongated in the second direction (y), and may be located between the first gate line GL1 and the second gate line GL2. The auxiliary pattern AP2a may be repeatedly located in the second direction (y). The auxiliary pattern AP2a may be connected to the common voltage line VL2 to reduce a resistance of the common voltage line VL2, and to reduce the RC delay of the common voltage ELVSS. The auxiliary pattern AP2a may be connected to the auxiliary pattern AP2b through a contact hole formed in the second insulating layer 150, and may be connected to the common voltage line VL2 through contact holes formed in the second insulating layer 150 and the buffer layer 120. Accordingly, the auxiliary pattern AP2b may be connected to the common voltage line VL2 through the auxiliary pattern AP2a.

The auxiliary pattern AP3a of the initialization voltage line VL3 may overlap the initialization voltage line VL3. The auxiliary pattern AP3a may be elongated in the second direction (y), and may be located between the first gate line GL1 and the second gate line GL2. The auxiliary pattern AP3a may be repeatedly located in the second direction (y). The auxiliary pattern AP3a may be connected to the initialization voltage line VL3 to reduce a resistance of the initialization voltage line VL3, and to reduce the RC delay of the initialization voltage INIT. The auxiliary pattern AP2a may be connected to the initialization voltage line VL3 through contact holes formed in the second insulating layer 150 and the buffer layer 120, and may be connected to the first area of the semiconductor layer A3 through a contact hole formed in the second insulating layer 150. Accordingly, the third transistor T3 may be connected to the initialization voltage line VL3 through the auxiliary pattern AP2a.

The third conductive layer may further include a connection member CM1 connecting the data lines DL1, DL2, and DL3 and the first area of the semiconductor layer A2, and may further include a connection member CM2 connecting the first electrode C1 of the storage capacitor Cst and the second area of the semiconductor layer A2. The connection member CM1 may be connected to the data lines DL1, DL2, and DL3 through contact holes formed in the second insulating layer 150 and in the buffer layer 120, and may be connected to the first area of the semiconductor layer A2 through a contact hole formed in the second insulating layer 150. The connection member CM2 may be connected to the first electrode C1 through a contact hole formed in the second insulating layer 150, and may be connected to the second area of the semiconductor layer A2 through a contact hole formed in the second insulating layer 150. Accordingly, the second transistor T2 may be connected to the data lines DL1, DL2, and DL3 through the connection member CM1, and may be connected to the first electrode C1 through the connection member CM2.

The third conductive layer may include a metal, such as copper (Cu), aluminum (A1), titanium (Ti), molybdenum (Mo), tungsten (W), or the like, and may be a single layer or multiple layers. The third conductive layer may include a transparent conductive material, such as indium tin oxide (ITO) or indium zinc oxide (IZO). For example, the third conductive layer may have a triple-layer structure, such as titanium (Ti)/copper (Cu)/ITO.

A third insulating layer 160 may be located on the third conductive layer. The third insulating layer 160 may be referred to as a passivation layer. The third insulating layer 160 may be an inorganic insulating layer including an inorganic insulating material, such as silicon oxide, silicon nitride, silicon oxynitride, or the like, and may be a single layer or multiple layers.

A first organic insulating layer 170 may be located on the third insulating layer 160. The first organic insulating layer 170 may be referred to as a planarization layer. The first organic insulating layer 170 may include an organic insulating material, such as a general-purpose polymer (e.g., poly(methyl methacrylate) or polystyrene), a polymer derivative having a phenol-based group, an acryl-based polymer, an imide-based polymer (e.g., polyimide), a siloxane-based polymer, or the like.

A fourth conductive layer that may include a pixel electrode E1 of the light-emitting diode LED, a connection electrode CE, and the like, may be located on the first organic insulating layer 170. Components included in the fourth conductive layer may be formed of the same material in the same process. FIG. 11 shows the first conductive layer, the semiconductor layers A1, A2, and A3, the second conductive layer, the third conductive layer, and the fourth conductive layer.

The pixel electrode E1 may be connected to the second electrode C2 through a contact hole H1 formed in the first organic insulating layer 170. The pixel electrode E1 may be connected to the second area of the semiconductor layer A1 via the second electrode C2. Each pixel electrode E1 may include an area portion with an approximately quadrangular shape and a protruding portion that is connected to the area portion and protrudes through the contact hole H1.

The connection electrode CE may include an extension portion CEa and a line portion connected to the extension portion CEa. The line portion may include a first vertical portion CEb and a second vertical portion CEe extending approximately in the second direction (y), and a first horizontal portion CEc and a second horizontal portion CEd extending approximately in the first direction (x). The extension portion CEa and the line portion may be integrally formed in the same conductive layer.

The extension portion CEa may have a greater width than that of the line portion. The extension portion CEa may overlap the common voltage line VL2 and the auxiliary patterns AP2a and AP2b. The extension portion CEa may be connected to the auxiliary pattern AP2a of the common voltage line VL2 through contact holes H2 formed in the first organic insulating layer 170 and the third insulating layer 160. Each extension portion CEa may include an area portion with a polygonal shape (e.g., an approximately octagonal shape) and a rod-shaped portion that is connected to the area portion and that protrudes through the contact hole H2. A width in the first direction (x) of the rod-shaped portion of the extension portion CEa may be less than a width in the first direction (x) of the area portion of the extension portion CEa.

Referring to FIG. 3 and FIG. 11, each of the first horizontal portion CEc and the second horizontal portion CEd may cross the first vertical portion CEb, and may form an approximately right angle with the first vertical portion CEb. The first horizontal portion CEc may be located between two second horizontal portions CEd adjacent to each other in the second direction (y), and may be located adjacent to one end of the extension portion CEa. The first horizontal portion CEc may start from the first vertical portion CEb adjacent to one end of the extension portion CEa to extend in the first direction (x), and may end at a position adjacent to the pixel electrode E1 of the pixels PX1, PX2, and PX3. The first horizontal portion CEc may be located closer to the extension portion CEa than to the second horizontal portion CEd. The first horizontal portion CEc may be located approximately in a center, or midway point, between two second horizontal portions CEd adjacent to each other in the second direction (y), but the present disclosure is not limited thereto. A length in the first direction (x) of the first horizontal portion CEc may be less than a length in the first direction (x) of the second horizontal portion CEd. Two first horizontal portions CEc adjacent to each other in the first direction (x) may be aligned in the first direction (x). The second horizontal portion CEd may be continuously formed between two first vertical portions CEb adjacent to each other in the first direction (x).

The second vertical portion CEe may be located between two first vertical portions CEb adjacent to each other in the first direction (x). The second vertical portion CEe may start from the second horizontal portion CEd to extend in the second direction (y), and may end at a position adjacent to the pixel electrode E1 of the pixels PX1, PX2, and PX3. The second vertical portion CEe may be located approximately in a center, or midway point, between two first vertical portions CEb adjacent to each other in the first direction (x), but the present disclosure is not limited thereto. A length in the second direction (y) of the second vertical portion CEe may be less than a length in the second direction (y) of the first vertical portion CEb. Two second vertical portions CEe adjacent to each other in the second direction (y) may be aligned in the second direction (y). The first vertical portion CEb may be continuously formed between two second horizontal portions CEd adjacent to each other in the second direction (y).

The first vertical portion CEb and the second horizontal portion CEd may surround three pixels PX1, PX2, and PX3 adjacent to each other together with the extension portion CEa. The extension portion CEa, the first vertical portion CEb, and the second horizontal portion CEd surrounding the three pixels PX1, PX2, and PX3 adjacent to each other may have an overall quadrangular shape, but the present disclosure is not limited thereto. When the adjacent pixels PX1, PX2, and PX3 are referred to as a unit pixel group, the extension portion CEa, the first vertical portion CEb, and the second horizontal portion CEd may extend along a boundary between adjacent unit pixel groups. The first horizontal portion CEc and the second vertical portion CEe may extend along a boundary between light-emitting areas or pixel electrodes E1 of the adjacent pixels PX1, PX2, and PX3 within each unit pixel group. For example, referring to FIG. 3 and FIG. 11, the first horizontal portion CEc may extend along a boundary between the light-emitting area or the pixel electrode E1 of the first pixel PX1 and the light-emitting area or the pixel electrode E1 of the second pixel PX2, and along a boundary between the light-emitting area or the pixel electrode E1 of the third pixel PX3 and the light-emitting area or the pixel electrode E1 of the second pixel PX2, and the second vertical portion CEe may extend along a boundary between the light-emitting area or the pixel electrode E1 of the first pixel PX1 and the light-emitting area or the pixel electrode E1 of the third pixel PX3.

The fourth conductive layer may be formed of a reflective conductive material or a semi-transmitting conductive material, or may be formed of a transparent conductive material. The pixel electrode E1 may include a transparent conductive material, such as indium tin oxide (ITO) or indium zinc oxide (IZO). The pixel electrode E1 may include a metal, such as lithium (Li), calcium (Ca), aluminum (A1), silver (Ag), magnesium (Mg), or gold (Au). The pixel electrode E1 may have a multi-layer structure, and for example, the pixel electrode E1 may have a triple-layer structure, such as ITO/silver (Ag)/ITO.

A second organic insulating layer 180 may be located on the fourth conductive layer. The second organic insulating layer 180 may be referred to as a pixel-defining layer. The second organic insulating layer 180 may include an organic insulating material, such as an acryl-based polymer, an imide-based polymer, or an amide-based polymer. The second organic insulating layer 180 may include a black pigment. For example, the second organic insulating layer 180 may include a polyimide binder and a mixture of red, green, and blue pigments. The second organic insulating layer 180 may include a cardo binder resin and a mixture of a lactam black pigment and a blue pigment. The second organic insulating layer 180 may include a carbon black. The second organic insulating layer 180 including the black pigment may improve a contrast ratio, and may reduce or prevent reflection by a metal layer located below the second organic insulating layer.

The second organic insulating layer 180 may cover an edge of the pixel electrode E1 and an edge of the extension portion CEa of the connection electrode CE. The second organic insulating layer 180 may be removed from an area other than an area covering the edge of the pixel electrode E1 and the edge of the extension portion CEa of the connection electrode CE. The second organic insulating layer 180 may have an opening OP1 that overlaps the pixel electrode E1, and may have an opening OP2 that overlaps the area portion of the extension portion CEa of the connection electrode CE. The openings OP1 and OP2 may be areas where the second organic insulating layer 180 is removed in the third direction z, which is the thickness direction. FIG. 12 shows the first conductive layer, the semiconductor layers A1, A2, and A3, the second conductive layer, the third conductive layer, the fourth conductive layer, and the removed region of the second organic insulating layer 180.

A light-emitting portion EL may be located on the fourth conductive layer. The light-emitting portion EL may include a plurality of layers, and at least some of the plurality of layers may be located across the pixels PX1, PX2, and PX3, and may be continuously located throughout the entire display area DA. The light-emitting portion EL may contact the pixel electrode E1 through the opening OP1 of the second organic insulating layer 180.

The light-emitting portion EL may have a light-emitting opening OP3 that overlaps the opening OP2. The light-emitting opening OP3 may overlap the common voltage line VL2 and the auxiliary patterns AP2a and AP2b. On a plane, the light-emitting opening OP3 may be surrounded by the opening OP2, and may be located within the opening OP2.

The light-emitting portion EL may include at least one light-emitting layer. The light-emitting layer may include a light-emitting material that emits blue light. The light-emitting layer may also include a light-emitting material that emits red light and/or green light in addition to blue light. The light-emitting layer may also include quantum dots. The light-emitting portion EL may include a plurality of light-emitting layers, and the plurality of light-emitting layers may include light-emitting layers that emit light of the same color, or may include light-emitting layers that emit light of different colors. For example, the light-emitting portion EL may have a structure in which three blue-light-emitting layers are stacked. As another example, the light-emitting portion EL may have a structure in which three blue-light-emitting layers and one green-light-emitting layer are stacked. In addition to the light-emitting layer, the light-emitting portion EL may include at least one of light-emitting auxiliary layers, such as a hole injection layer, a hole transport layer, an electron transport layer, an electron injection layer, and the like. The light-emitting auxiliary layer may be formed in each of the pixels PX1, PX2, and PX3, or may be continuously formed across the plurality of pixels PX1, PX2, and PX3.

A common electrode E2 may be located on the light-emitting portion EL. The common electrode E2 may be located across the pixels PX1, PX2, and PX3. The common electrode E2 may be continuously located across the entire display area DA. The common electrode E2 may be connected to the connection electrode CE through the light-emitting opening OP3 formed in the light-emitting portion EL. Because the connection electrode CE is connected to the common voltage line VL2, the common electrode E2 may be connected to the common voltage line VL2 through the connection electrode CE to receive the common voltage ELVSS. Accordingly, the common electrode E2 may substantially uniformly receive the common voltage ELVSS across the entire display area DA, and a voltage drop due to a resistance of the common electrode E2 may be improved, which may reduce or prevent luminance deviation occurring in the display area DA.

The light-emitting opening OP3 formed in the light-emitting portion EL to connect the common electrode E2 to the connection electrode CE may be formed by a laser drilling process. For example, after the light-emitting portion EL is formed, a laser may be irradiated on a portion of the light-emitting portion EL that overlaps the opening OP2 to remove the portion, and thus, the light-emitting opening OP3 that penetrates the light-emitting portion EL in the third direction z which is the thickness direction may be formed. Accordingly, the connection electrode CE that overlaps the light-emitting opening OP3 may be exposed. Then, if the common electrode E2 is formed, the common electrode E2 may be connected to the connection electrode CE through the light-emitting opening OP3.

The common electrode E2 may include a metal, such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), or the like. The common electrode E2 may include transparent conductive oxide, such as indium tin oxide (ITO) or indium zinc oxide (IZO). The common electrode E2 may have a multi-layer structure. For example, the common electrode E2 may have a double-layer structure, such as magnesium (Mg)/silver (Ag).

The pixel electrode E1, the light-emitting portion EL, and the common electrode E2 may form the light-emitting diode LED, which may be an organic light-emitting diode. The pixel electrode E1 may be individually provided for each of the pixels PX1, PX2, and PX3 to receive a driving current. The common electrode E2 may be commonly provided to the pixels PX1, PX2, and PX3 to receive the common voltage. The pixel electrode E1 may be an anode that is a hole injection electrode, and the common electrode E2 may be a cathode that is an electron injection electrode, or vice versa. The opening OP1 of the second organic insulating layer 180 may correspond to a light-emitting area of the light-emitting diode LED. A light-emitting area of each of the pixels PX1, PX2, and PX3 may be defined by the opening OP1 of the second organic insulating layer 180. The light-emitting area or the pixel electrode E1 of adjacent three pixels PX1, PX2, and PX3 may be located in an area surrounded by the extension portion CEa of the connection electrode CE, the second horizontal portion CEd, and the first vertical portion CEb.

Referring to FIG. 3 and FIG. 6, the line portion including the first horizontal portion CEc, the second horizontal portion CEd, the first vertical portion CEb, and the second vertical portion CEe of the connection electrode CE may form a discharge diode LEDc together with the light-emitting portion EL and the common electrode E2 overlapping the line portion. For convenience of description, the line portion of the connection electrode CE may also be referred to as a discharge electrode. The light-emitting portion EL included in the discharge diode LEDc may or may not include the light-emitting layer. As shown in FIG. 6, the second organic insulating layer 180 may be removed to form an opening OP4 in an area where the discharge diode LEDc is formed. For example, on a plane, the discharge diode LEDc may overlap the opening OP4 of the second organic insulating layer 180.

If the discharge diode LEDc includes the light-emitting layer, it may not emit light or may slightly emit light, but as described below (e.g., see FIG. 19), an area where the discharge diode LEDc is located may overlap a light-blocking area where a bank and/or a plurality of color filters with different colors overlap so that light may not be visible from the outside.

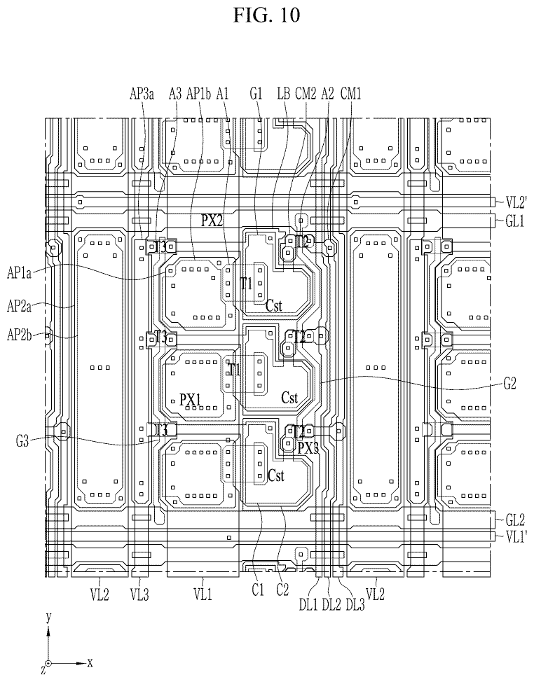

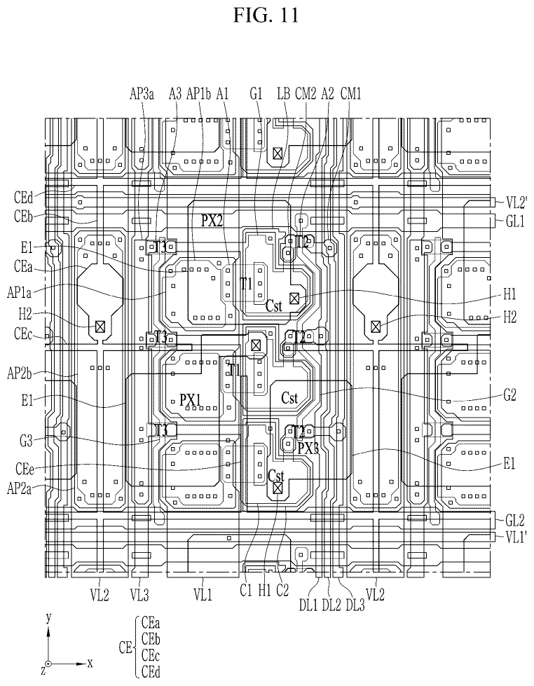

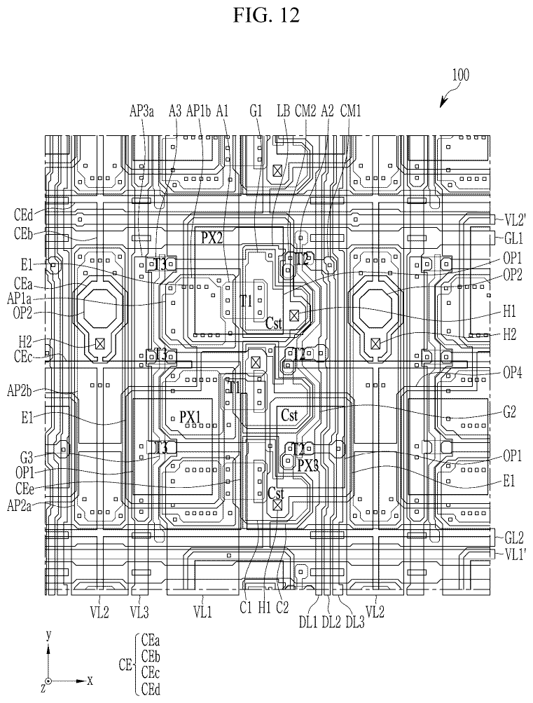

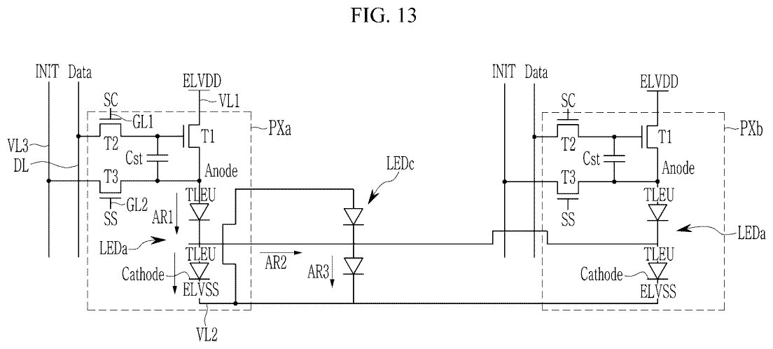

FIG. 13 is a circuit diagram for two pixels PXa and PXb of the display device according to one or more embodiments. Each pixel PXa or PXb shown in FIG. 13 may be one of the pixels PX1, PX2, and PX3 described above.

Referring to FIG. 13 together with the drawings described above, the discharge diode LEDc may be connected between two adjacent pixels PXa and PXb. A cathode of the discharge diode LEDc may be the common electrode E2 and may be connected to a cathode of a light-emitting diode LEDa of the pixel PXa, and an anode of the discharge diode LEDc may be the line portion of the connection electrode CE, may transfer the common voltage ELVSS, and may be connected to the cathode of the light-emitting diode LEDa of the pixel PXa.

As shown in FIG. 13, when the light-emitting diode LEDa is driven, a driving current AR1 may flow so that the light-emitting diode LEDa emits light. As shown in FIG. 13, if the discharge diode LEDc does not exist, a leakage current AR2 may occur toward the adjacent pixel PXb due to a light-emitting auxiliary layer between the cathode and an anode of the light-emitting diode LEDa, so that a light-emitting diode LEDa of the adjacent pixel PXb may also unintentionally emit light. This is referred to as leakage light emission. If the light-emitting auxiliary layer is continuously formed across the adjacent pixels PXa and PXb, leakage light emission may occur.

However, the discharge diode LEDc may be located between the light-emitting diodes LEDa of the adjacent pixels PXa and PXb, so that the leakage current AR2 flows toward the cathode (that is, the common electrode E2) to reduce or prevent the unintended leakage light emission of the adjacent pixel PXb.

Because the discharge diode LEDc, which has maintained therein a constant voltage, such as the common voltage, is located between the adjacent pixels PXa and PXb, crosstalk due to coupling between the adjacent pixels PXa and PXb may also be reduced or prevented.

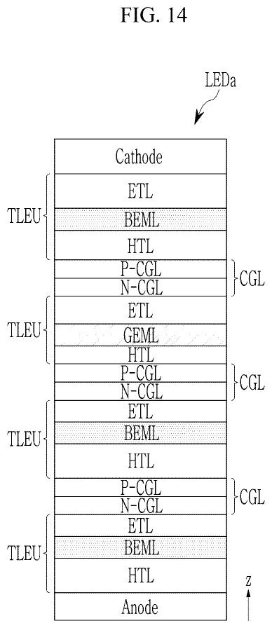

FIG. 14 is a cross-sectional view of a light-emitting diode included in one pixel of the display device according to one or more embodiments.

Referring to FIG. 14 together with the drawings described above, the light-emitting diode LEDa included in the display device may include a plurality of unit light-emitting portions TLEU located between the anode, which may be the pixel electrode E1 and the cathode, which may be the common electrode E2. When the display device displays an image, each light-emitting diode LEDa may include the plurality of unit light-emitting portions, and thus, efficiency of the light-emitting diode LEDa may be increased, and a display characteristic of the image may be improved. The light-emitting portion EL described above may include the plurality of unit light-emitting portions TLEU.

Each unit light-emitting portion TLEU may include a light-emitting auxiliary layer (e.g., a hole transport layer HTL, an electron transport layer ETL, or the like) and a light-emitting layer BEML or GEML. For example, FIG. 14 shows a structure in which three blue light-emitting layers BEML and one green light-emitting layer GEML of the plurality of unit light-emitting portions TLEU are stacked in the third direction z. A charge generation layer CGL may be located between adjacent unit light-emitting portions TLEU. The charge generation layer CGL may include an n-type charge generation layer N-CGL and a p-type charge generation layer P-CGL. In each pixel, the n-type charge generation layer N-CGL and the p-type charge generation layer P-CGL may be in contact to form an NP junction. An electron and a hole may be simultaneously generated between the n-type charge generation layer N-CGL and the p-type charge generation layer P-CGL by the NP junction. At least some of the n-type charge generation layer N-CGL and the p-type charge generation layer P-CGL may be continuously formed across the plurality of pixels.

Although the light-emitting diode LEDa of each pixel PXa or PXb shown in FIG. 13 includes two unit light-emitting portions TLEU shown in FIG. 14, the present disclosure is not limited thereto, and each light-emitting diode LEDa may include three or more unit light-emitting portions TLEU. The discharge diode LEDc may include an anode and a cathode connected to the cathode of the light-emitting diode LEDa, and may include a light-emitting auxiliary layer, such as the charge generation layer CGL, located between the anode and the cathode. The discharge diode LEDc may include two or more unit light-emitting portions TLEU, such as the light-emitting diode LEDa.

Referring to FIG. 13 and FIG. 14, the leakage current AR2 may suitably flow through the charge generation layer CGL located between adjacent unit light-emitting portions TLEU of the light-emitting diode LEDa, but as described above, the leakage current AR2 may be discharged toward the common electrode E2 through the discharge diode LEDc to reduce or prevent the unintended leakage light emission of the adjacent pixel PXb.

Referring back to FIGS. 3 to 12, an encapsulation layer 190 may be located on the common electrode E2. The encapsulation layer 190 may seal light-emitting diodes LED, and may reduce or prevent moisture or oxygen penetrating from the outside. The encapsulation layer 190 may cover the entire display area DA, and an edge of the encapsulation layer 190 may be located in the non-display area NA.

The encapsulation layer 190 may be a thin-film encapsulation layer including a first inorganic layer 191, an organic layer 192, and a second inorganic layer 193. The first inorganic layer 191 and the second inorganic layer 193 may reduce or prevent penetration of moisture or the like, and the organic layer 192 may planarize a surface of the encapsulation layer 190 (for example, a surface of the second inorganic layer 193 in the display area DA). The first inorganic layer 191 and the second inorganic layer 193 may include an inorganic insulating material, such as silicon oxide, silicon nitride, or the like. The organic layer 192 may include an organic material, such as an acryl-based resin, a methacryl-based resin, polyisoprene, a vinyl-based resin, an epoxy-based resin, a urethane-based resin, a cellulose-based resin, or a perylene-based resin, or the like.

The first inorganic layer 191 and the second inorganic layer 193 may be wider than the organic layer 192, and the first inorganic layer 191 and the second inorganic layer 193 may be in contact near the edge of the encapsulation layer 190. An edge of the first inorganic layer 191 and an edge of the second inorganic layer 193 may roughly coincide. The first inorganic layer 191 and the second inorganic layer 193 may be relatively wider, and thus, penetration of moisture or oxygen from a side surface of the display area DA may be reduced or prevented, and the penetration may be delayed by lengthening and complicating a penetration path of the moisture or the oxygen.

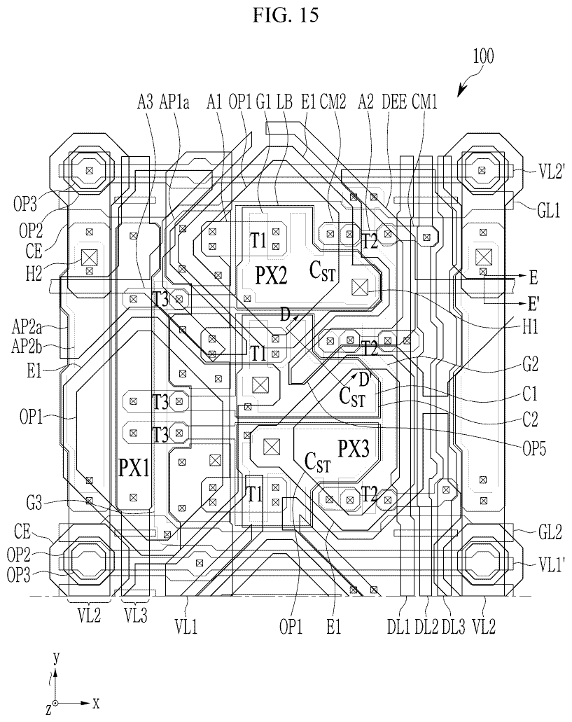

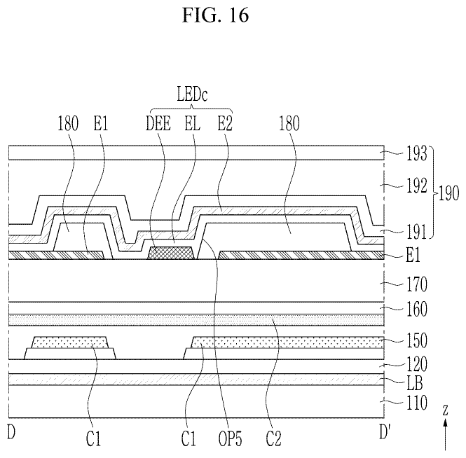

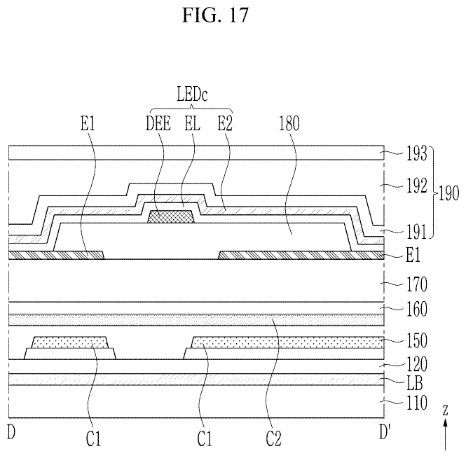

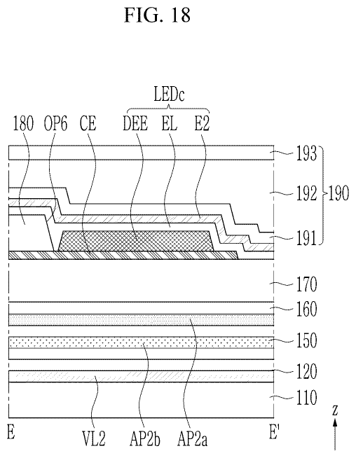

FIG. 15 is a plan view of a display portion of a display device according to one or more embodiments, FIG. 16 is a cross-sectional view of the display device shown in FIG. 15 that is cut along the line D-D′, FIG. 17 is a cross-sectional view of the display device shown in FIG. 15 that is cut along the line D-D′, and FIG. 18 is a cross-sectional view of the display device shown in FIG. 15 that is cut along the line E-E′.

Although a disposition, shape, and the like of components of the display device shown in FIGS. 15 to 18 are different from those of the embodiments described above, a connection relationship between the components may be substantially the same as that of the display device described above.

For example, a first conductive layer including the data lines DL1, DL2, and DL3, the driving voltage line VL1, the common voltage line VL2, the initialization voltage line VL3, the light-blocking pattern LB, and the like may be located on the substrate 110 of the display device. The data lines DL1, DL2, and DL3, the driving voltage line VL1, the common voltage line VL2, and the initialization voltage line VL3 may extend in the second direction (y).

A buffer layer 120 may be located on the first conductive layer. Semiconductor layers A1, A2, and A3 of the transistors T1, T2, and T3 may be located on the buffer layer 120. A first insulating layer 140 may be located on the semiconductor layers A1, A2, and A3. A second conductive layer that may include the gate electrodes G1, G2, and G3 of the transistors T1, T2, and T3, the first electrode C1 of the storage capacitor Cst, the auxiliary pattern AP2b of the common voltage line VL2, and the like may be located on the first insulating layer 140.

A second insulating layer 150 may be located on the second conductive layer. A third conductive layer that may include the first gate line GL1, the second gate line GL2, the second electrode C2 of the storage capacitor Cst, an auxiliary driving voltage line VL1′, an auxiliary common voltage line VL2′, an auxiliary pattern AP1a of the driving voltage line VL1, an auxiliary pattern AP2a of the common voltage line VL2, the connection member CM1 or CM2, and the like, may be located on the second insulating layer 150. The first gate line GL1, the second gate line GL2, the auxiliary driving voltage line VL1′, and the auxiliary common voltage line VL2′ may extend in the first direction (x). The first gate line GL1 may be connected to the gate electrode G2 through a contact hole formed in the second insulating layer 150. The second gate line GL2 may be connected to the gate electrode G3 through a contact hole formed in the second insulating layer 150. The second electrode C2 may form the storage capacitor Cst together with the first electrode C1. The auxiliary driving voltage line VL1′ may be connected to the driving voltage line VL1 through contact holes formed in the second insulating layer 150 and the buffer layer 120. The auxiliary common voltage line VL2′ may be connected to the common voltage line VL2 through contact holes formed in the second insulating layer 150 and the buffer layer 120. The auxiliary pattern AP1a may be connected to the driving voltage line VL1 through contact holes formed in the second insulating layer 150 and the buffer layer 120, and may be connected to the first area of the semiconductor layer A1 through a contact hole formed in the second insulating layer 150. The auxiliary pattern AP2a may be connected to the auxiliary pattern AP2b through a contact hole formed in the second insulating layer 150, and may be connected to the common voltage line VL2 through contact holes formed in the second insulating layer 150 and the buffer layer 120. The connection member CM1 may be connected to the data lines DL1, DL2, and DL3 through contact holes formed in the second insulating layer 150 and the buffer layer 120, and may be connected to the first area of the semiconductor layer A2 through a contact hole formed in the second insulating layer 150. The connection member CM2 may be connected to the first electrode C1 through a contact hole formed in the second insulating layer 150, and may be connected to the second area of the semiconductor layer A2 through a contact hole formed in the second insulating layer 150.

A third insulating layer 160 may be located on the third conductive layer. A first organic insulating layer 170 may be located on the third insulating layer 160. A fourth conductive layer that may include a pixel electrode E1 of the light-emitting diode, a connection electrode CE, and the like, may be located on the first organic insulating layer 170. The pixel electrode E1 may be connected to the second electrode C2 through a contact hole H1 formed in the first organic insulating layer 170. The connection electrode CE may be connected to the auxiliary pattern AP2a of the common voltage line VL2 through contact holes H2 formed in the first organic insulating layer 170 and the third insulating layer 160.

A second organic insulating layer 180 having (e.g., defining) an opening OP1 that overlaps the pixel electrode E1, and having an opening OP2 that overlaps the connection electrode CE, may be located on the fourth conductive layer. The opening OP1 may define a light-emitting area of each of the pixels PX1, PX2, and PX3

The opening OP2 may overlap the common voltage line VL2 and the auxiliary common voltage line VL2′.

A light-emitting portion EL having a light-emitting opening OP3 that overlaps the opening OP2 may be located on the fourth conductive layer.

A common electrode E2 may be located on the light-emitting portion EL. The common electrode E2 may be connected to the connection electrode CE through the light-emitting opening OP3 formed in the light-emitting portion EL, and may receive the common voltage ELVSS through the connection electrode CE. An encapsulation layer 190 that may include a first inorganic layer 191, an organic layer 192, and a second inorganic layer 193 may be located above the light-emitting portion EL.

The display device may further include a discharge electrode DEE located between the first organic insulating layer 170 and the light-emitting portion EL. The second organic insulating layer 180 may be omitted from between the discharge electrode DEE and the light-emitting portion EL. In a manufacturing method of the display device according to one or more embodiments, the discharge electrode DEE may be formed after formation of the second organic insulating layer 180. The discharge electrode DEE may be located at a conductive layer different from that of the connection electrode CE, and may be formed at a manufacturing step different from that of the connection electrode CE.

Referring to FIG. 15, the discharge electrode DEE may include a line portion extending along a boundary between light-emitting areas or pixel electrodes E1 of the pixels PX1, PX2, and PX3 adjacent on a plane.

Referring to FIG. 15 and FIG. 18, the discharge electrode DEE may be electrically connected to the connection electrode CE by contacting the connection electrode CE in an opening OP6 of the second organic insulating layer 180. The discharge electrode DEE may overlap the connection electrode CE on a plane at a portion of the discharge electrode DEE connected to the connection electrode CE. A portion of the discharge electrode DEE that overlaps the connection electrode CE may extend approximately in the first direction (x). The discharge electrode DEE may be connected to the common voltage line VL2 through the connection electrode CE to receive the common voltage ELVSS.

The pixel electrode E1, the light-emitting portion EL, and the common electrode E2 may form the light-emitting diode LED or LEDa, as previously described. Referring to FIG. 15 and FIG. 18, the discharge electrode DEE may form a discharge diode LEDc together with the light-emitting portion EL and the common electrode E2 that overlap the discharge electrode DEE, and that are located above the discharge electrode DEE. As shown in FIG. 16, in an area where the discharge diode LEDc is formed, the second organic insulating layer 180 may be removed to form an opening OP5, so that the discharge electrode DEE overlaps the opening OP5. According to one or more other embodiments, as shown in FIG. 17, in the area where the discharge diode LEDc is formed, the second organic insulating layer 180 may not be removed, and the discharge electrode DEE may overlap the second organic insulating layer 180. In this case, the discharge electrode DEE may contact an upper surface of the second organic insulating layer 180.

A function and a characteristic of the discharge diode LEDc may be the same as those described with reference to FIG. 13 and FIG. 14, so the same description is not repeated here.

According to one or more other embodiments, an anode of the discharge diode LEDc may receive a constant voltage different from the common voltage ELVSS. In this case, the discharge electrode DEE may be connected to an electrode capable of transferring a constant voltage that is other than the connection electrode CE.

FIG. 19 is a cross-sectional view of a display panel of the display device according to one or more embodiments.

Referring to FIG. 19, the display panel 10 may include a display portion 100, a color conversion portion 200, and a filler 400 located between the display portion 100 and the color conversion portion 200.

The display portion 100 may be the same as that described above. For example, the display portion 100 may include a substrate 110, a transistor TR formed above the substrate 110, and a light-emitting diode LED connected to the transistor TR. The transistor TR may include a semiconductor layer AL, a gate electrode GE, a first electrode SE, and a second electrode DE. The first electrode SE may be connected to a first area of the semiconductor layer AL and a light-blocking pattern LB, and the second electrode DE may be connected to a second area of the semiconductor layer AL. The transistor TR may be the first transistor T1 described above.

The color conversion portion 200 may be located above an encapsulation layer 190 of the display portion 100.

The color conversion portion 200 may include a substrate 210. The substrate 210 may include an insulating material, such as glass or plastic. For example, the substrate 210 may be a glass substrate.

Color filters 230a, 230b, and 230c may be located on the substrate 210 in a direction toward the display portion 100. In the display area DA, the color filters 230a, 230b, and 230c may overlap the openings OP1 of the second organic insulating layer 180. The color filters 230a, 230b, and 230c may include the first color filter 230a that transmits light of a first wavelength and that absorbs light of a remaining wavelength, a second color filter 230b that transmits light of a second wavelength and that absorbs light of a remaining wavelength, and a third color filter 230c that transmits light of a third wavelength and that absorbs light of a remaining wavelength. The first color filter 230a, the second color filter 230b, and the third color filter 230c may overlap a first pixel PX1, a second pixel PX2, and a third pixel PX3, respectively. This can increase the purity of light of the first wavelength (corresponding to the first pixel PX1), the second wavelength (corresponding to the second pixel PX2), and the third wavelength (corresponding to the third pixel PX3) emitted outside of the display panel 10. Light of the first wavelength, light of the second wavelength, and light of the third wavelength may be red light, green light, and blue light, respectively.

The first color filter 230a, the second color filter 230b, and the third color filter 230c may overlap between the pixels PX1, PX2, and PX3 to form a light-blocking area. The first color filter 230a, the second color filter 230b, and the third color filter 230c may all overlap to form the light-blocking area, but two color filters may also overlap to form the light-blocking area. The light-blocking area may be provided by forming a light-blocking member instead of overlapping the color filters 230a, 230b, and 230c.

A low-refractive index layer 240 may be located on the color filters 230a, 230b, and 230c. The low-refractive index layer 240 may cover an entire substrate 210. The low-refractive index layer 240 may include an organic material or an inorganic material having a low-refractive index. The refractive index of the low-refractive index layer 240 may be about 1.1 to about 1.3. The low-refractive index layer 240 may be located at a position different from that shown in the drawings. For example, the low-refractive index layer 240 may be located between a second capping layer 280 and each of color conversion layers 270a and 270b and/or a transmission layer 270c. The color conversion portion 200 may include a plurality of low-refractive index layers. For example, as shown in the drawings, the color conversion portion 200 may further include the low-refractive index layer located between the second capping layer 280 and each of the color conversion layers 270a and 270b and/or the transmission layer 270c in addition to the low-refractive index layer 240 located between the color filters 230a, 230b, and 230c and a first capping layer 250.

The first capping layer 250 may be located on the low-refractive index layer 240. The first capping layer 250 may entirely cover the low-refractive index layer 240, and may protect the low-refractive index layer 240. The first capping layer 250 may include an inorganic insulating material, such as silicon oxide, silicon nitride, silicon oxynitride, or the like, and may be a single layer or multiple layers.

A bank 260 may be located on the first capping layer 250. The bank 260 may be located in the display area DA, and may overlap the second organic insulating layer 180. The bank 260 may overlap a light-blocking area that overlaps the first color filter 230a, the second color filter 230b, and the third color filter 230c. The bank 260 may be located at a boundary portion between the pixels PX1, PX2, and PX3. The bank 260 may divide or define a pixel area. The bank 260 may include an organic insulating material, such as an acryl-based polymer, an imide-based polymer, or an amide-based polymer. The bank 260 may be a black bank including a colored pigment, such as a black pigment, or may be transparent in other embodiments.

The first color conversion layer 270a, the second color conversion layer 270b, and the transmission layer 270c may be located on the first capping layer 250. The first color conversion layer 270a, the second color conversion layer 270b, and the transmission layer 270c may be located within a space defined by the bank 260 (e.g., an opening of the bank 260). The first color conversion layer 270a, the second color conversion layer 270b, and the transmission layer 270c may be divided or separated by the bank 260. The first color conversion layer 270a, the second color conversion layer 270b, and the transmission layer 270c may be formed by an inkjet printing process.

The first color conversion layer 270a may overlap the first color filter 230a. The first color conversion layer 270a may overlap the light-emitting diode LED corresponding to the first pixel PX1, and may convert light incident from the light-emitting diode LED into light of the first wavelength. Light of the first wavelength may be red light having a maximum light-emitting peak wavelength (e.g., about 600 nm to about 650 nm, or about 620 nm to about 650 nm).

The second color conversion layer 270b may overlap the second color filter 230b. The second color conversion layer 270b may overlap the light-emitting diode LED corresponding to the second pixel PX2, and may convert light incident from the light-emitting diode LED into light of the second wavelength. Light of the second wavelength may be green light having a maximum light-emitting peak wavelength (e.g., about 500 nm to about 550 nm, or about 510 nm to about 550 nm).

The transmission layer 270c may overlap the third color filter 230c. The transmission layer 270c may overlap the light-emitting diode LED corresponding to the third pixel PX3, and may transmit light incident from the light-emitting diode LED. Light transmitted through the transmission layer 270c may be light of the third wavelength. Light of the third wavelength may be blue light having a maximum light-emitting peak wavelength (e.g., about 380 nm to about 480 nm, about 420 nm or more, about 430 nm or more, about 440 nm or more, about 445 nm or more, about 470 nm or less, about 460 nm or less, and/or about 455 nm or less).

The first color conversion layer 270a and the second color conversion layer 270b may include first quantum dots and second quantum dots, respectively. For example, light incident on the first color conversion layer 270a may be converted into light of the first wavelength by the first quantum dots to be emitted. Light incident on the second color conversion layer 270b may be converted into light of the second wavelength by the second quantum dots to be emitted. The first color conversion layer 270a, the second color conversion layer 270b, and the transmission layer 270c may include scatterers. The scatterers may improve optical efficiency by scattering light incident on the first color conversion layer 270a, the second color conversion layer 270b, and the transmission layer 270c.

Each of the first quantum dots and the second quantum dots (hereinafter also referred to as a first semiconductor nanocrystal and a second semiconductor nanocrystal) may independently include a Group II-VI compound, a Group III-V compound, a Group IV-VI compound, a Group IV element or compound, a Group I-III-VI compound, a Group II-III-VI compound, a Group I-II-IV-VI compound, or a combination thereof.

The quantum dots may have a core-shell structure including a core including the nanocrystal and a shell surrounding the core. The shell of the quantum dots may serve as a protective layer for maintaining a semiconductor characteristic by reducing or preventing chemical denaturation of the core and/or a charging layer for imparting an electrophoretic characteristic to the quantum dots. The shell may be a single layer or multiple layers. An interface between the core and the shell may have a concentration gradient in which a concentration of an element present in the shell decreases toward a center thereof. An example of the shell of the quantum dots may include metal oxide, non-metal oxide, a semiconductor compound, or a combination thereof.

The quantum dots may have a full width of half maximum (e.g., about 45 nm or less, about 40 nm or less, or about 30 nm or less) of a light-emitting wavelength spectrum, and may improve color purity or color reproducibility within a range of the full width of half maximum. Additionally, because light emitted through the quantum dots is emitted in all directions, a viewing angle may be improved.

In the quantum dots, a material of the shell and a material of the core may have different energy bandgaps. For example, the energy bandgap of the material of the shell may be greater than or less than that of the material of the core. The quantum dots may have a shell having multiple layers. In the shell having multiple layers, an energy bandgap of an outer layer thereof may be larger than an energy bandgap of an inner layer thereof (e.g., a layer closer to the core). In the shell having multiple layers, the energy bandgap of the outer layer may be less than the energy bandgap of the inner layer.

The quantum dots may include an organic ligand (e.g., the organic ligand having a hydrophobic residue and/or a hydrophilic residue). A residue of the organic ligand may be coupled to a surface of the quantum dots. The organic ligand may include RCOOH, RNH₂, R₂NH, R₃N, RSH, R₃PO, R₃P, ROH, RCOOR, RPO(OH)₂, RHPOOH, R₂POOH, or a combination thereof. Here, R may be independently a C₃ to C₄₀ substituted or unsubstituted aliphatic hydrocarbon group (e.g., C₃ to C₄₀ or C₅ to C₂₄ substituted or unsubstituted alkyl, C₃ to C₄₀ or C₅ to C₂₄ substituted or unsubstituted alkenyl, or the like), a C₆ to C₄₀ or C₆ to C₂₀ substituted or unsubstituted aromatic hydrocarbon group (e.g., a C₆ to C₄₀ substituted or unsubstituted aryl group or the like), or a combination thereof.

The second capping layer 280 may be located on the bank 260 in a direction toward the display portion 100. The second capping layer 280 may entirely cover the substrate 210. The second capping layer 280 may cover the first color conversion layer 270a, the second color conversion layer 270b, and the transmission layer 270c. The second capping layer 280 may include an inorganic insulating material, such as silicon oxide, silicon nitride, silicon oxynitride, or the like, and may be a single layer or multiple layers.

The low-refractive index layer 240, the first capping layer 250, and the second capping layer 280 may cover side surfaces of the color filters 230a, 230b, and 230c at an edge portion of the color conversion portion 200. The low-refractive index layer 240, the first capping layer 250, and the second capping layer 280 may be formed up to an edge of the substrate 210, and the low-refractive index layer 240 may be in contact with the substrate 210 at the edge of the color conversion portion 200. The low-refractive index layer 240, the first capping layer 250, and the second capping layer 280 may form a blocking member that reduces or prevents moisture, oxygen, or the like penetrating from the edge of the color conversion portion 200.

The filler 400 may be located between the color conversion portion 200 and the display portion 100. The filler 400 may fill a space between the display portion 100 and the color conversion portion 200 to increase pressing resistance between the display portion 100 and the color conversion portion 200. One surface of the filler 400 may be in contact with the second capping layer 280, and the other surface of the filler 400 may be in contact with the encapsulation layer 190. The filler 400 may be formed by applying a filler material on the second capping layer 280 and overlapping the display portion 100, and by then curing the filler material. The filler 400 may include an organic material, such as an epoxy resin.

The display device according to the above embodiments can be applied to various electronic devices. An electronic device according to an embodiment comprises the aforementioned display device and may further comprise a module or a device with additional functions other than the display device.

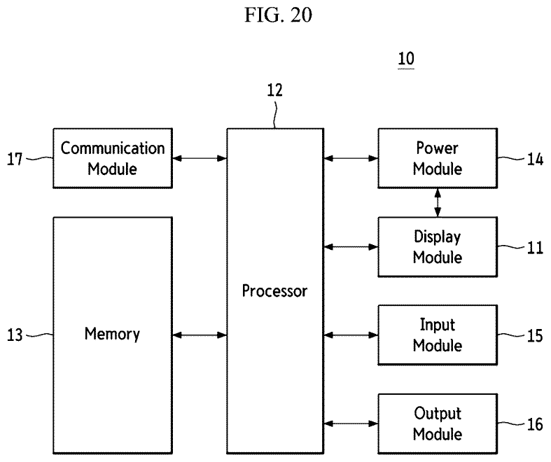

FIG. 20 is a block diagram of an electronic device according to an embodiment. Referring to FIG. 20, an electronic device 10 according to an embodiment may comprise a display module 11, a processor 12, a memory 13, and a power module 14. The electronic device 10 may further comprise an input module 15, a non-visual output module 16, and/or a communication module 17. The display module may comprise a display device according to an embodiment as described above.

The electronic device 10 may output various information in the form of images via the display module 11. When the processor 12 executes an application stored in the memory 13, an image information provided from the application may be provided to a user via the display module 11. The power module 14 may comprise a power supply module such as a power adapter or a battery device, and a power conversion module that converts the power supplied by the power supply module to generate the power necessary for operation of the electronic device 10. The input module 15 may provide an input information to the processor 12 and/or the display module 11. The non-visual output module 16 may receive information other than the image information, such as sound, haptic, or light information provided from the processor 12, and provide it to the user. The communication module 17 is responsible for transmitting and receiving information between the electronic device 10 and an external device, and may comprise a receiver and a transmitter.

At least one of the aforementioned components of the electronic device 11 may be included within the display device according to the above-described embodiments. In addition, some of the individual modules that are functionally included in one module may be included within the display device, while others may be provided separately from the display device. For example, a display device according to an embodiment may include the display module 11, while the processor 12, the memory 13, and the power module 14 may be provided in a form of other devices within the electronic device 11, not within the display device.

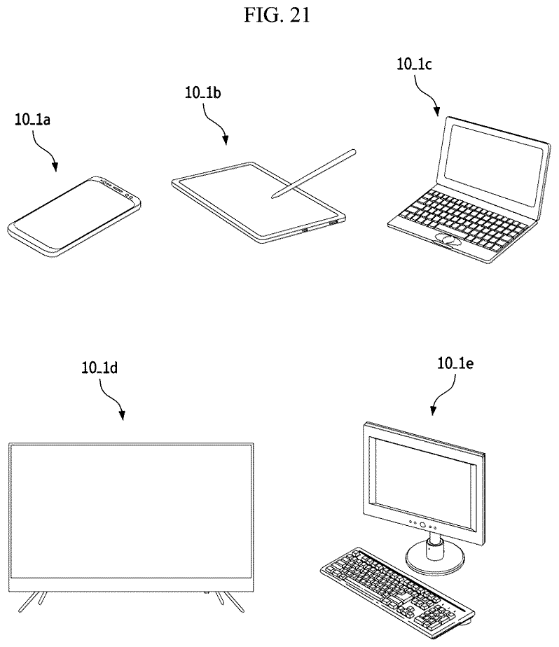

FIG. 21 to FIG. 23 are schematic diagrams of electronic devices according to various embodiments. FIG. 21 to FIG. 23 illustrate examples of various electronic devices to which a display device according to an embodiment is applied.

FIG. 21 illustrates examples of electronic devices, including a smartphone 10_1a, a tablet PC 10_1b, a laptop 10_1c, a TV 10_1d, and a desktop monitor 10_1e.

A smartphone 10_1a may comprise an input module such as a touch sensor and a communication module in addition to the display module 11. The smartphone 10_1a may process information received through the communication module or other input modules and display the information through the display module of the display device.

Each of the tablet PC 10_1b, the laptop 10_1c, the TV 10_1d, and the desktop monitor 10_1e may comprise a display module and an input module similar to the smartphone 10_1a, and may additionally comprise a communication module depending on embodiments.

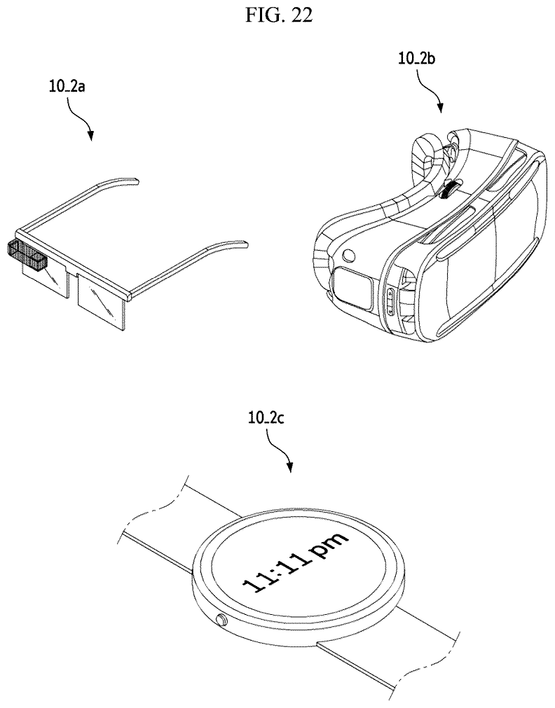

FIG. 22 illustrates an example where an electronic device including a display module is applied to a wearable electronic device. The wearable electronic device may be smart glasses 10_2a, a head-mounted display 10_2b, a smart watch 10_2c, and so on.

The smart glasses 10_2a and the head-mounted display 10_2b may comprise a display module that projects display images and a reflector that reflects the projected display images to provide it to a user's eyes, through which, a screen of virtual reality or augmented reality may be provided to the user.

The smart watch 10_2c may comprise a biometric sensor as an input device, and may provide biometric information recognized through the biometric sensor to a user via a display module.

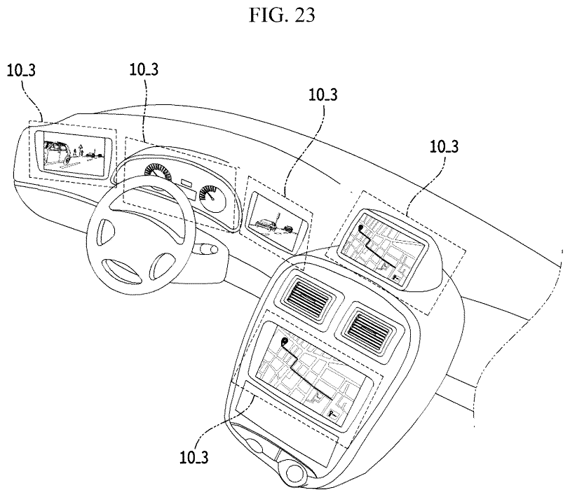

FIG. 23 illustrates an example of an electronic device including a display module applied to a vehicle. For example, an electronic device 10_3 may be applied to an instrument panel, or a center fascia, etc. of a car, or it may be applied to a CID (Center Information Display) placed on a dashboard of a car, or it may be applied to a room mirror display replacing a side mirror.

Although not illustrated, an electronic device to which a display device according to embodiments is applied may include not only devices primarily focused on screen display such as a billboard, an electronic signboard, and a gaming machine, but also various home appliances that display information through a display module, such as a refrigerator, a washing machine, a dryer, an air conditioner, and a robot vacuum cleaner. Furthermore, when the display module has a light-transmitting function, it can be applied to an electronic device such as a smart window or a transparent display device that show both the background and a displayed image. The types of electronic devices according to the embodiments are not limited to the examples given above, and application to various other electronic devices not mentioned may also be possible.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

Description of Some Reference Characters

| | |
|---|---|
| 10: display panel | 100: display portion |
| 110: substrate | 120: buffer layer |
| 140: first insulating layer | 150: second insulating layer |
| 160: third insulating layer | 170: first organic insulating layer |
| 180: second organic insulating layer | 200: color conversion portion |
| 400: filler | A1, A2, A3, AL: semiconductor layer |
| AP1a, AP1b, AP2a, AP2b, AP3a: auxiliary pattern | |
| C1: first electrode | C2: second electrode |
| CE: connection electrode | CM1, CM2: connection member |
| Cst: storage capacitor | DA: display area |
| DEE: discharge electrode | DL, DL1, DL2, DL3: data line |
| E1: pixel electrode | E2: common electrode |
| EL: light-emitting portion | G1, G2, G3, GE: gate electrode |
| GL1: first gate line | GL2: second gate line |
| H1, H2: contact hole | LB: light-blocking pattern |
| NA: non-display area | LED, LEDa: light-emitting diode |
| LEDc: discharge diode | OP1, OP2, OP4, OP5, OP6: opening |
| OP3: light-emitting opening | PX, PX1, PX2, PX3, PXa, PXb: pixel |
| T1, T2, T3, TR: transistor | TLEU: unit light-emitting portion |
| VL1: driving voltage line | VL1′: auxiliary driving voltage line |
| L2: common voltage line | VL2′: auxiliary common voltage line |
| VL3: initialization voltage line | |

What is claimed is:

1. A display device comprising:
a substrate;
a common voltage line above the substrate;
a first insulating layer above the common voltage line;
a connection electrode above the first insulating layer, and electrically connected to the common voltage line through a first contact hole of the first insulating layer;
a pixel electrode above the first insulating layer;
a light-emitting portion above the pixel electrode, and defining a light-emitting opening above the connection electrode;
a common electrode above the light-emitting portion, and electrically connected to the connection electrode through the light-emitting opening; and
a discharge electrode above the first insulating layer, electrically connected to the connection electrode, extending along a space between two or more adjacent pixel electrodes comprising the pixel electrode in plan view, and overlapping the light-emitting portion and the common electrode to form a discharge diode.

2. The display device of claim 1, further comprising a second insulating layer above the pixel electrode, and defining a first opening overlapping the pixel electrode, a second opening overlapping the light-emitting opening, and a third opening overlapping the discharge diode.

3. The display device of claim 2, wherein the discharge electrode is at a same conductive layer as the connection electrode, and is integrally formed with the connection electrode.

4. The display device of claim 3, wherein the display device comprises unit pixel groups repeatedly arranged, and comprising adjacent pixels,
wherein the discharge electrode comprises a first horizontal portion extending in a first direction, and a first vertical portion extending in a second direction crossing the first direction, the first horizontal portion and the first vertical portion surrounding one of the unit pixel groups with the connection electrode in plan view.

5. The display device of claim 4, wherein the discharge electrode comprises a second horizontal portion extending in the first direction, and a second vertical portion extending in the second direction,
wherein the second horizontal portion is between two adjacent first horizontal portions comprising the first horizontal portion, and has a shorter length than that of the first horizontal portion, and
wherein the second vertical portion is between two adjacent first vertical portions comprising the first vertical portion, and has a shorter length than that of the first vertical portion.

6. The display device of claim 5, wherein the second horizontal portion and the second vertical portion extend along a space between the adjacent pixels of one of the unit pixel groups.

7. The display device of claim 6, wherein the second horizontal portion is at a center between the two adjacent first horizontal portions in plan view.

8. The display device of claim 2, wherein the discharge electrode is at a conductive layer that is different from the connection electrode, and comprises a portion overlapping the connection electrode in plan view.

9. The display device of claim 8, wherein the display device comprises unit pixel groups repeatedly arranged and comprising adjacent pixels, and
wherein the discharge electrode comprises a portion extending along a space between the adjacent pixels of one of the unit pixel groups.

10. The display device of claim 9, wherein a portion of the discharge electrode overlapping the connection electrode crosses the common voltage line.

11. The display device of claim 1, further comprising a second insulating layer above the pixel electrode, and defining a first opening overlapping the pixel electrode and a second opening overlapping the light-emitting opening,
wherein the discharge electrode is above an upper surface of the second insulating layer.

12. The display device of claim 11, wherein the discharge electrode is at a conductive layer that is different from the connection electrode, and comprises a portion overlapping the connection electrode in plan view.

13. The display device of claim 12, wherein the display device comprises unit pixel groups repeatedly arranged and comprising adjacent pixels, and
wherein the discharge electrode comprises a portion extending along a space between the adjacent pixels of the unit pixel group.

14. A display device comprising:
a substrate;
a first transistor and a second transistor above the substrate;
a first light-emitting diode and a second light-emitting diode respectively connected to the first transistor and the second transistor, and comprising a pixel electrode, a common electrode, and a light-emitting portion between the pixel electrode and the common electrode and comprising stacked unit light-emitting portions and a light-emitting auxiliary layer between adjacent ones of the unit light-emitting portions, the unit light-emitting portions comprising a light-emitting layer comprising a light-emitting material; and
a discharge diode connected between the first light-emitting diode and the second light-emitting diode, and comprising the light-emitting auxiliary layer and an anode and a cathode connected to a cathode of the first light-emitting diode.

15. The display device of claim 14, wherein the light-emitting auxiliary layer in the first light-emitting diode and in the discharge diode comprises a charge generation layer.

16. The display device of claim 14, further comprising:
a common voltage line above the substrate; and
a connection electrode connected to the common voltage line,
wherein the light-emitting portion defines a light-emitting opening above the connection electrode, and
wherein the cathode of the first light-emitting diode is connected to the connection electrode through the light-emitting opening.

17. The display device of claim 16, wherein the anode of the discharge diode is at a same conductive layer as the connection electrode, and is integrally formed with the connection electrode.

18. The display device of claim 17, further comprising an insulating layer between an anode and the cathode of the first light-emitting diode, and defining a first opening overlapping the anode of the first light-emitting diode, a second opening overlapping the light-emitting opening, and a third opening overlapping the anode of the discharge diode.

19. The display device of claim 16, wherein the anode of the discharge diode is at a conductive layer that is different from the connection electrode, and comprises a portion overlapping the connection electrode in plan view.

20. The display device of claim 19, further comprising an insulating layer between an anode and the cathode of the first light-emitting diode, and defining a first opening overlapping the anode of the first light-emitting diode and a second opening overlapping the light-emitting opening,
wherein the anode of the discharge diode is above an upper surface of the insulating layer.

21. An electronic device comprising a display device comprising a display device comprising:
a substrate;
a common voltage line above the substrate;
a first insulating layer above the common voltage line;
a connection electrode above the first insulating layer, and electrically connected to the common voltage line through a first contact hole of the first insulating layer;
a pixel electrode above the first insulating layer;
a light-emitting portion above the pixel electrode, and defining a light-emitting opening above the connection electrode;
a common electrode above the light-emitting portion, and electrically connected to the connection electrode through the light-emitting opening; and
a discharge electrode above the first insulating layer, electrically connected to the connection electrode, extending along a space between two or more adjacent pixel electrodes comprising the pixel electrode in plan view, and overlapping the light-emitting portion and the common electrode to form a discharge diode.

22. The electronic device of claim 21, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
